(19) United States
(12) Patent Application Publication
(10) Pub. No.: US 2009/0155933 A1
(43) Pub. Date: Jun. 18, 2009

(54) Manufacturing Method of Display Device

(76) Inventors: Ken OHARA, Chiba (JP); Tsunenori Yamamoto, Hitachi (JP); Susumu Edo, Mobara (JP); Yoshiaki Nakayoshi, Oamishirasato (JP); Hiroshi Saito, Fujisawa (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 12/331,546

(22) Filed: Dec. 10, 2008

(30) Foreign Application Priority Data
Dec. 14, 2007 (JP) 2007-323607

(51) Int. Cl. H01L 21/66; H01L 33/00

(52) U.S. Cl. 438/14; 438/34; 257/E33.001; 257/E21.531

(57) ABSTRACT

To suppress the occurrence of image quality irregularities in a liquid crystal display device having a TFT substrate which is manufactured by performing steps a plurality of times in such a manner that one region is divided into a plurality of exposure regions, and the plurality of exposure regions is exposed. In a manufacturing method of a display device which performs, for a preliminarily determined one region on a surface of an insulation substrate, an exposure/development step including a step of exposing a formed film made of a photosensitive material and a step of developing an exposed film made of the photosensitive material a plurality of times, said each exposure step is performed such that said one region is divided into the plurality of exposure regions by a boundary line which has no overlapping portion and is not aligned with a boundary line between the exposure regions in the exposure step for at least one time out of other exposure steps, and the whole of said one region is exposed by individually exposing the respective exposure regions.

### CROSS-REFERENCE TO RELATED APPLICATIONS

The disclosure of Japanese Patent Application No. 2007-323607 filed on Dec. 14, 2007 including the specification, drawings and abstract is incorporated herein by reference in its entirety.

### BACKGROUND OF THE INVENTION

1. Field of the Invention

The present invention relates to a manufacturing method of a display device, and more particularly to a technique which is effectively applicable to a manufacturing method of a TFT substrate of a liquid crystal display panel used in a liquid crystal display device.

2. Description of the Related Arts

A liquid crystal display device such as a liquid crystal television receiver set or a liquid crystal monitor of a PC (personal computer) has a liquid crystal display panel which is formed by filling a liquid crystal material between a pair of substrates.

With respect to one substrate out of the above-mentioned pair of substrates, on a surface of an insulation substrate formed of a glass substrate or the like, a plurality of scanning signal lines, a plurality of video signal lines, a plurality of TFT elements which is arranged in a matrix array, pixel electrodes which are connected to the TFT elements and the like are formed. This substrate is referred to as a TFT substrate in general. Further, with respect to another substrate out of the above-mentioned pair of substrates, on a surface of an insulation substrate formed of a glass substrate or the like, a light blocking film referred to as a black matrix, color filters and the like are formed.

Further, a display region of the liquid crystal display panel is formed of a mass of pixels each of which have the TFT element and the pixel electrode, and each pixel includes the pixel electrode, a counter electrode, and a pixel capacitance (also referred to as a liquid crystal capacitance) which is formed of the liquid crystal material. When the liquid crystal display panel is of a lateral-electric-field drive method (for example, IPS method), the counter electrodes are formed on the TFT substrate. Further, when the liquid crystal display panel is of a vertical-electric-field drive method (for example, TN method or VA method), the counter electrodes are formed on the counter substrate.

Further, when the liquid crystal display panel is of the lateral-electric-field drive method, the pixel electrodes and the counter electrodes may be arranged on the same plane of one insulation layer in an opposed manner at predetermined intervals, or may be arranged in a stacked manner with an insulation layer consisting of one layer or more therebetween.

In a manufacturing method of the TFT substrate, a step of forming the scanning signal line, a step of forming the video signal lines (including source electrodes and drain electrodes of the TFT elements), and a step of forming the pixel electrodes are usually steps independent from each other, wherein these portions are formed by forming a conductive film having a predetermined film thickness (film forming) and, thereafter, by etching the conductive film. Accordingly, in the manufacturing method of the TFT substrate, in a process for forming the scanning signal line, the video signal line, the TFT substrate, the pixel electrode and the like on one region which is preliminarily determined on a surface of the insulation substrate, a step of forming an etching resist is performed a plurality of times. That is, in the manufacturing method of the TFT substrate, an exposure/development including a step of exposing a film made of a photosensitive material which is formed on a surface of the conductive film or a semiconductor film or a step of developing the exposed film made of the photosensitive material is performed a plurality of times.

In the conventional manufacturing method of the TFT substrate, the exposure step for one time is performed such that, in general, the above-mentioned one region is exposed at a time using a photomask, for example. However, large-sizing of a screen has been in progress recently with respect to a liquid crystal television receiver set or a liquid crystal monitor and hence, the above-mentioned one region requires a larger area. Accordingly, the conventional exposure method which uses a photo mask pushes up a manufacturing cost of the photo mask, for example. There also arises a drawback that a manufacturing yield ratio of the TFT substrate is lowered.

To cope with the above-mentioned drawbacks, with respect to a recent manufacturing method of a TFT substrate, for example, there has been proposed a method which performs exposure using a direct-drawing exposure method (also referred to as a direct exposure method). The direct-drawing exposure method is an exposure method which does not use the above-mentioned photo mask. That is, the direct-drawing exposure method is a method which uses a light source which can expose a region smaller than the above-mentioned one region at a time, the light source scans a region which can be exposed by the light source and directly draws a pattern (a latent image) formed of a photosensitive region and a non-photosensitive region in the whole one region. In directly drawing the above-mentioned pattern, for example, the above-mentioned one region is divided into a large number of minute regions, the large number of minute regions are calcified into the minute regions to be exposed and the minute regions not to be exposed based on layout data (numerical value data) prepared by a CAD or the like, and the minute regions to be exposed are sequentially or collectively exposed.

In case of the above-mentioned direct-drawing exposure method, when an area of the region which can be exposed at a time using one light source is increased, time necessary for exposure can be shortened. However, the number of minute regions included in the region which can be exposed at a time is increased and hence, a control for radiating light to only the minute regions to be exposed in the region becomes complicated. To the contrary, when an area of the region which can be exposed at a time using one light source becomes small, the number of minute regions included in the region which can be exposed at a time is decreased. Accordingly, although a control for radiating light to only the minute regions to be exposed in the region becomes easy, time necessary for exposure is prolonged. Accordingly, as a method for efficiently performing the exposure by the above-mentioned direct-drawing exposure method, for example, there has been proposed a method which uses a plurality of independent light sources, and exposes the whole of the above-mentioned one region while simultaneously exposing a plurality of portions of the above-mentioned one region (see U.S. Pat. No. 5,945,256 (patent document 1), for example). In this method, by performing the exposure using two independent light sources, for example, time necessary for exposure can be halved compared to a case in which the exposure is performed using one light source.

### SUMMARY OF THE INVENTION

However, in forming the etching resist, when the method which exposes the whole of the above-mentioned one region by dividing the above-mentioned one region into the plurality of exposure regions and by individually exposing the respective exposure regions is used, for example, the displacement in position or size of the formed etching resist is liable to occur on a boundary portion between two neighboring exposure regions.

That is, in forming the etching resist on the conductive film for forming a plurality of video signal lines, the displacement is liable to occur between a width of the etching resist formed on one exposure region and a width of the etching resist formed on another separate exposure region adjacent to the above-mentioned one exposure region. Accordingly, in forming the plurality of video signal lines by etching the conductive film, for example, there may be a case that the widths of the video signal lines which are respectively formed on the above-mentioned two exposure regions are largely changed on the boundary portion between the above-mentioned two exposure regions.

Further, in forming the pixel electrodes, for example, there may be a case that sizes of the pixel electrodes which are formed in two neighboring exposure regions respectively are largely changed on a boundary portion between the above-mentioned two exposure regions.

Further, in the conventional manufacturing method of the TFT substrate, in exposure steps which are performed a plurality of times in a process of manufacturing one TFT substrate, the boundary line between the exposure regions passes the same position in general. That is, the boundary line between the exposure regions at the time of forming the plurality of scanning signal lines, the boundary line between the exposure regions at the time of forming the plurality of video signal lines, and the boundary line between the exposure regions at the time of forming the pixel electrodes pass the same position on the insulation substrate.

Under such circumstances, in forming the etching resist, when the method which exposes the whole of the above-mentioned one region by dividing the above-mentioned one region into the plurality of exposure regions and by individually exposing the respective exposure regions is used, the acquired liquid crystal display panel (liquid crystal display device) has a drawback that image quality is liable to be changed at a position corresponding to the boundary between two neighboring exposure regions thus giving rise to the easy occurrence of image quality irregularities.

Accordingly, it is an object of the present invention to provide, with respect to a liquid crystal display device having a TFT substrate which is manufactured by performing steps of exposing the whole of the above-mentioned one region a plurality of times in such a manner that the above-mentioned one region is divided into a plurality of exposure regions and the exposure regions are individually exposed, a manufacturing method of such a liquid crystal display device which can suppress the occurrence of image quality irregularities.

The above-mentioned object, other objects and novel features of the present invention will become apparent from the description of this specification and attached drawings.

To briefly explain the summary of typical inventions among the inventions disclosed in this specification, they are as follows.

(1) The present invention is directed to a manufacturing method of a display device which performs, in a series of processes of forming a plurality of scanning signal lines, a plurality of video signal lines, a plurality of TFT elements and a plurality of pixel electrodes on a preliminarily determined one region on a surface of an insulation substrate, an exposure/development step including a step of exposing a formed film made of a photosensitive material and a step of developing an exposed film made of the photosensitive material a plurality of times, wherein said each exposure step is performed using an exposure device such that the whole of said one region is exposed by dividing said one region into a plurality of exposure regions and by individually exposing the respective exposure regions, and said each exposure step is performed such that said one region is divided into the plurality of exposure regions by a boundary line which has no overlapping portion with and is not aligned with a boundary line between the exposure regions in the exposure step for at least one time out of other exposure steps, and the plurality of exposure regions is exposed.

(2) In the manufacturing method of the display device having the constitution (1), the boundary line between the exposure regions in the exposure step which is performed for forming the video signal lines is not aligned with the boundary line between the exposure regions in the exposure step which is performed for forming the pixel electrodes.

(3) In the manufacturing method of the display device having the constitution (1) or (2), said one region is divided into a plurality of exposure regions using a boundary line which is constituted of a line segment which extends in an extension direction of the video signal lines formed in said one region and a line segment which extends in an extension direction of the scanning signal lines formed in said one region.

(4) In the manufacturing method of the display device having the constitution (3), the exposure step which is performed for forming the video signal lines is performed such that said one region is divided into the plurality of exposure regions by the boundary line which does not pass a region of said one region where the TFT element is formed, and the plurality of exposure regions is exposed.

(5) In the manufacturing method of the display device having the constitution (3) or (4), the exposure step which is performed for forming the pixel electrodes is performed such that said one region is divided into the plurality of exposure regions by the boundary line which does not pass a region of said one region where the pixel electrode is formed, and the plurality of exposure regions is exposed.

(6) In the manufacturing method of the display device having any one of the constitutions (3) to (5), the exposure step which is performed for forming the pixel electrodes is performed such that said one region is divided into the plurality of exposure regions by the boundary line which is constituted of a line segment which passes a region of said one region where the video signal line is formed and a line segment which passes a region of said one region where the scanning signal line passes, and the plurality of exposure regions is exposed.

(7) The present invention is also directed to a manufacturing method of a display device which performs, in a process of forming a plurality of scanning signal lines, a plurality of video signal lines, a plurality of TFT elements and a plurality of pixel electrodes on a preliminarily determined one region on a surface of an insulation substrate, an exposure/development step including a step of exposing a formed film made of a photosensitive material and a step of developing an exposed film made of the photosensitive material a plurality of times, wherein said each exposure step is performed using an exposure device such that the whole of said one region is exposed by dividing said one region into a plurality of exposure regions and by individually exposing the respective exposure regions, and said each exposure step is performed such that said one region is divided into the plurality of exposure regions in a state that a boundary portion of two neighboring exposure regions has a partial region where two neighboring regions overlap with each other, and said one partial region is divided into a plurality of first small regions which forms a portion of one exposure region out of said two neighboring exposure regions and a plurality of second small regions which forms a portion of another exposure region out of said two neighboring exposure regions in a mosaic arrangement, and the small regions are exposed.

(8) In the manufacturing method of the display device having the constitution (7), the partial regions of the respective exposure steps overlap with each other, and the arrangement of the first small regions and the second small regions in said one partial region in each exposure step is set different from the arrangement of the first small regions and the second small regions of the partial region which overlaps with the partial region in the exposure step for at least one time out of said other exposure steps.

(9) In the manufacturing method of the display device having the constitution (8), the arrangement of the first small regions and the second small regions in the partial region in the exposure step which is performed for forming the video signal lines is set different from the arrangement of the first small regions and the second small regions in the partial region in the exposure step which is performed for forming the pixel electrodes.

(10) The present invention is also directed to a manufacturing method of a display device which performs, in a series of processes of forming a plurality of scanning signal lines, a plurality of video signal lines, a plurality of TFT elements and a plurality of pixel electrodes on a preliminarily determined one region on a surface of an insulation substrate, an exposure/development step including a step of exposing a formed film made of a photosensitive material and a step of developing an exposed film made of the photosensitive material a plurality of times, wherein said each exposure step is performed using an exposure device such that the whole of said one region is exposed by dividing said one region into a plurality of exposure regions and by individually exposing the exposure regions, and said each exposure step is performed such that said one region is divided into the plurality of exposure regions in a state that a boundary portion of two neighboring exposure regions has a partial region where two neighboring regions overlap with each other, and the partial region is exposed together with one exposure region out of said two neighboring exposure regions and, thereafter, is exposed together with another exposure region out of said neighboring exposure regions.

(11) In the manufacturing method of the display device having the constitution (10), said one partial region is exposed such that a sum of exposure quantity for the partial region is substantially equal to exposure quantity for said one exposure region and exposure quantity for said another exposure region.

(12) In the manufacturing method of the display device having the constitution (10) or (11), said each exposure step is performed such that said one region is divided into the plurality of exposure regions while preventing a portion or the whole of the partial region from overlapping with the partial region in the exposure step for at least one time out of said other exposure steps.

(13) In the manufacturing method of the display device having the constitution (12), the partial region in the exposure step which is performed for forming the video signal lines has a partial region or the whole region thereof not overlapped with the partial region in the exposure step which is performed for forming the pixel electrodes.

(14) In the manufacturing method of the display device having any one of the constitutions (1) to (13), the counter electrodes are formed together with the pixel electrodes at the time of forming the pixel electrodes.

(15) In the manufacturing method of the display device having any one of the constitutions (1) to (14), the exposure device includes a plurality of photo masks which is prepared for the respective exposure regions and, in the exposure step for one time, the plurality of exposure regions is sequentially exposed by repeating an exchange of the photo masks and moving of an exposure position.

(16) In the manufacturing method of the display device having any one of the constitutions (1) to (14), the exposure device includes a plurality of independent light sources, a moving means which moves relative positions between the respective light sources and the insulation substrate, and a control means which controls radiation/non-radiation of lights from the light source based on preliminarily prepared numerical data, and in the exposure step for one time, the different exposure regions are exposed in parallel using the plurality of respective light sources.

(17) In the manufacturing method of the display device having the constitution (16), in addition to said series of processes for forming the plurality of scanning signal lines, the plurality of video signal lines, the plurality of TFT elements and the plurality of pixel electrodes on said one region out of the surface of the insulation substrate, the manufacturing method further comprises the steps of: measuring at least one of a size of the plurality of scanning signal lines formed through the process, a size of the plurality of video signal lines formed through the process, a size of a plurality of TFT elements formed through the process, and a size of the plurality of pixel electrodes formed through the process; and comparing the sizes measured in the measuring step and the numerical data used in the exposure step which is performed for forming an object whose size has been measured, and correcting the numerical data when necessary, and the measuring step and the correcting step are performed individually for every exposure region.

According to the manufacturing method of the display device of the present invention, the liquid crystal display device having the TFT substrate is manufactured as follows. That is, the exposure/development step consisting of the step of exposing the formed film made of the photosensitive material on one region and the step of developing the exposed film is performed the plurality of times, and the exposure step for one time is performed such that one region is divided into the plurality of exposure regions, and the respective exposure regions are individually exposed thus exposing the whole of such one region. Accordingly, the manufacturing method of the display device of the present invention can easily suppress image quality irregularities which occur in the liquid crystal display device, particularly, image quality irregularities which occur in the vicinity of a boundary between two neighboring exposure regions in the liquid crystal display device.

### BRIEF DESCRIPTION OF THE DRAWINGS

FIG. 1A is a schematic plan view showing one example of the planar constitution of a liquid crystal display panel;

FIG. 1B is a schematic cross-sectional view showing one example of the cross-sectional constitution of a liquid crystal display panel taken along a line A-A′ in FIG. 1A;

FIG. 1C is a schematic plan view showing one example of an arrangement method of scanning signal lines and video signal lines on a TFT substrate of the liquid crystal display panel;

FIG. 2A is a schematic plan view showing one example of the planar constitution of a region where one pixel occupies on the TFT substrate 1 and a periphery of the region;

FIG. 2B is a schematic cross-sectional view showing one example of the cross-sectional constitution of the TFT substrate 1 taken along a line B-B′ in FIG. 2A;

FIG. 2C is a schematic cross-sectional view showing one example of the cross-sectional constitution of the TFT substrate 1 taken along a line C-C′ in FIG. 2A;

FIG. 3A is a schematic plan view showing one example of the manufacturing method of the TFT substrate for simultaneously manufacturing two TFT substrates;

FIG. 3B is a schematic plan view showing one example of a conventional exposure method applied to one region shown in FIG. 3A;

FIG. 3C is a schematic plan view showing another example of the conventional exposure method applied to one region shown in FIG. 3A;

FIG. 3D is an enlarged plan view of a region shown in FIG. 3B and FIG. 3C;

FIG. 4A is a schematic plan view showing one example of an exposure method of a photosensitive resist which is performed for forming video signal lines;

FIG. 4B is a schematic plan view showing one example of an exposure method of a photosensitive resist which is performed for forming pixel electrodes and counter electrodes;

FIG. 4C is a schematic plan view for explaining the manner of operation and advantageous effects of the exposure method of the embodiment 1;

FIG. 5A is a schematic plan view showing a modification of the exposure method of the photosensitive resist which is performed for forming pixel electrodes and counter electrodes;

FIG. 5B is a schematic plan view for explaining the manner of operation and advantageous effects of the exposure method of the modification shown in FIG. 5A;

FIG. 6A is a schematic plan view showing one example of an exposure method of a photosensitive resist which is performed for forming video signal lines;

FIG. 6B is a schematic plan view showing one example of an exposure method of a photosensitive resist which is performed for forming pixel electrodes and counter electrodes;

FIG. 6C is a schematic plan view for explaining the manner of operation and advantageous effects of an exposure method of an embodiment 2;

FIG. 7A is a schematic plan view showing one example of an exposure method using a second light source which is performed for forming video signal lines;

FIG. 7B is a schematic cross-sectional view showing one example of respective photosensitive patterns in a first exposure region, a second exposure region and a third exposure region shown in FIG. 7A;

FIG. 7C is a schematic plan view showing one example of an exposure method using a first light source which is performed for forming video signal lines;

FIG. 7D is a schematic cross-sectional view showing one example of respective photosensitive patterns in the first exposure region, the second exposure region and the third exposure region shown in FIG. 7C;

FIG. 7E is a schematic cross-sectional view showing one example of cross-sectional shapes of resists respectively formed in the first exposure region, the second exposure region and the third exposure region;

FIG. 8A is a schematic plan view showing one example of an exposure method using a second light source which is performed for forming pixel electrodes and counter electrodes;

FIG. 8B is a schematic plan view showing one example of an exposure method using a first light source which is performed for forming pixel electrodes and counter electrodes; and

FIG. 9 is a schematic graph for explaining a modification of the manufacturing method of a TFT substrate of an embodiment 3.

### DETAILED DESCRIPTION OF THE INVENTION

Hereinafter, the present invention is explained in detail in conjunction with modes or embodiments by reference to drawings.

Here, in all drawings for explaining the embodiments, parts having identical functions are given the same symbols and their repeated explanation is omitted.

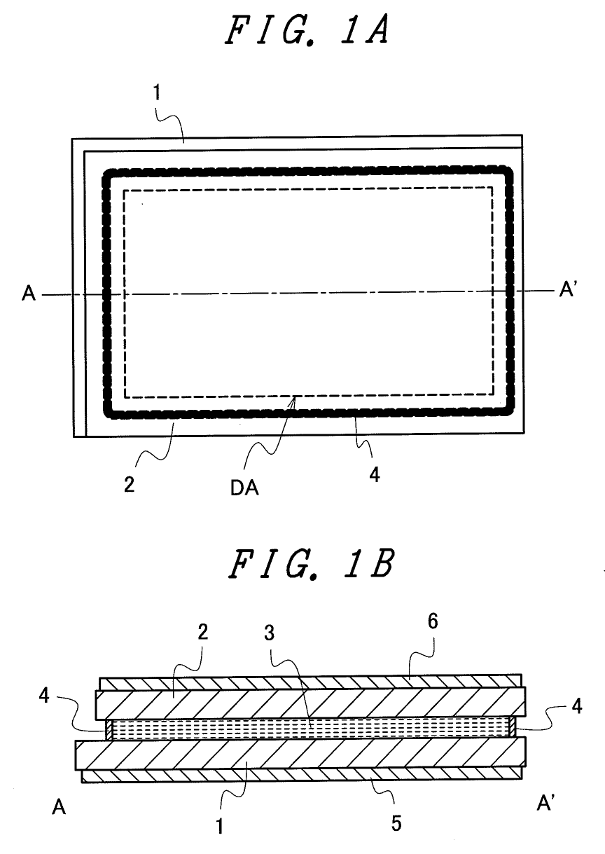

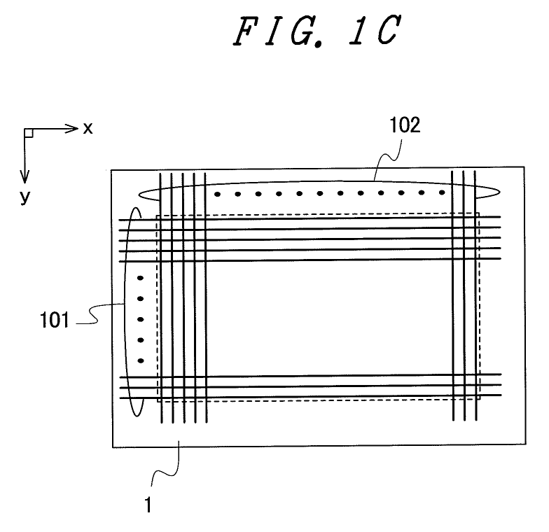

FIG. 1A to FIG. 1C are schematic views showing one example of the schematic constitution of a liquid crystal display panel according to the present invention.

FIG. 1A is a schematic plan view showing one example of the planar constitution of the liquid crystal display panel. FIG. 1B is a schematic cross-sectional view showing one example of the cross-sectional constitution of the liquid crystal display panel taken along a line A-A′ in FIG. 1A. FIG. 1C is a schematic plan view showing one example of an arrangement method of scanning signal lines and video signal lines on a TFT substrate of the liquid crystal display panel.

Here, the x direction and the y direction in FIG. 1C are equal to the x direction and the y direction adopted in FIG. 1A.

The present invention is applicable to a manufacturing method of a TFT substrate of a liquid crystal display panel used in a liquid crystal display device such as a liquid crystal monitor connected to a liquid crystal television receiver set or a personal computer, for example. The liquid crystal display panel includes, for example, as shown in FIG. 1A and FIG. 1B, a TFT substrate 1, a counter substrate 2, a liquid crystal material 3, a sealing member 4, a lower polarizer 5 and an upper polarizer 6. Further, a display region DA of the liquid crystal display panel is a region which is constituted of a mass of a plurality of pixels.

The TFT substrate 1 is, for example, as shown in FIG. 1C, a substrate which includes a plurality of scanning signal lines 101, a plurality of video signal lines 102, a plurality of TFT elements, a plurality of pixels and the like not shown in the drawing. Here, the scanning signal lines 101, the video signal lines 102, the TFT elements, the pixel electrodes and the like are formed on a surface of an insulation substrate such as a glass substrate. Further, the respective video signal lines 102 intersect the plurality of scanning signal lines 101 by way of an insulation layer.

A region which one pixel occupies on the TFT substrate corresponds to, for example, a region surrounded by two neighboring scanning signal lines 101 and two neighboring video signal lines 102.

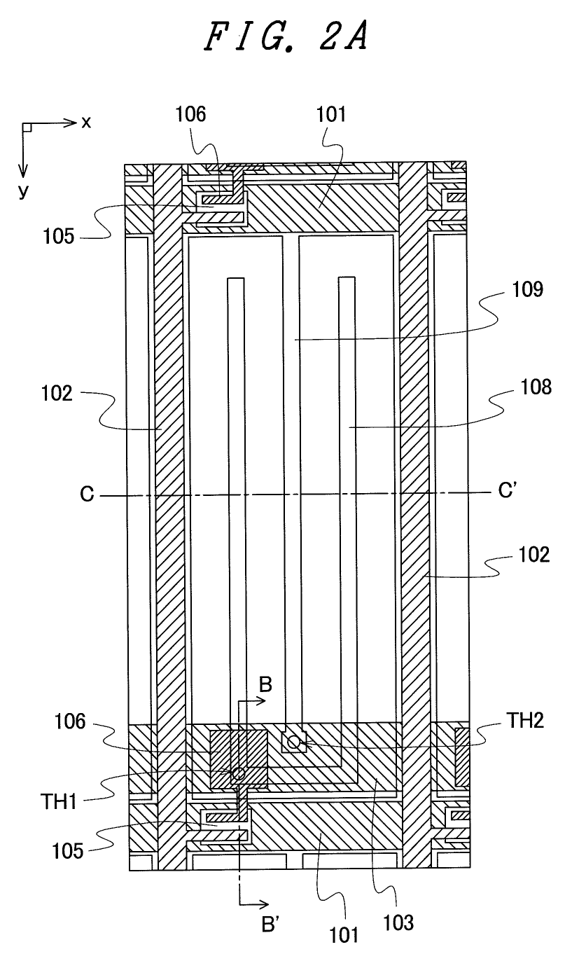

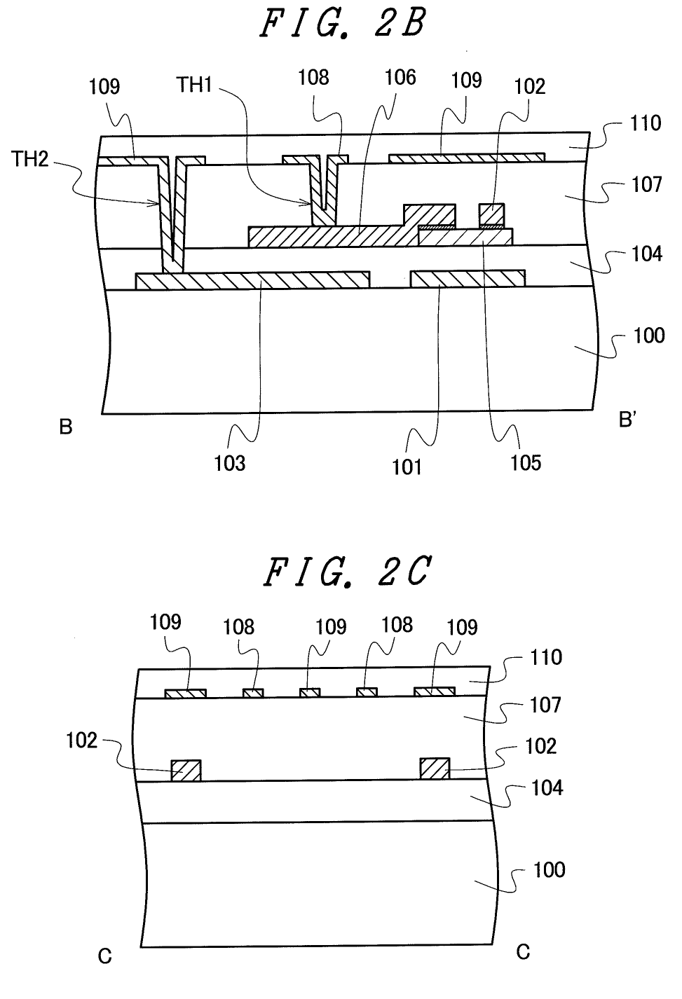

FIG. 2A to FIG. 2C are schematic views showing one example of the schematic constitution of one pixel on the TFT substrate 1.

FIG. 2A is a schematic plan view showing one example of the planar constitution of the region which one pixel occupies and a periphery of the region on the TFT substrate 1. FIG. 2B is a schematic cross-sectional view showing one example of the cross-sectional constitution of the TFT substrate 1 taken along a line B-B′ in FIG. 2A. FIG. 2C is a schematic cross-sectional view showing one example of the cross-sectional constitution of the TFT substrate 1 taken along a line C-C′ in FIG. 2A.

Here, the x direction and the y direction in FIG. 2A are equal to the x direction and the y direction in FIG. 1A.

Although the present invention is basically applicable to the TFT substrate 1 having any constitution, in the explanation of the specification made hereinafter, the explanation is made by taking an example in which one pixel on the TFT substrate 1 has the constitution shown in FIG. 2A to FIG. 2C, for example. The constitution shown in FIG. 2A to FIG. 2C is a constitutional example of one pixel on the TFT substrate 1 used in a liquid crystal display panel of a lateral-electric-field drive method.

Here, with respect to the TFT substrate 1, on a surface of an insulation substrate 100 formed of a glass substrate, for example, the scanning signal lines 101, holding capacitance lines 103, a first insulation layer 104, semiconductor layers 105 of TFT elements, video signal lines 102 (including drain electrodes of the TFT elements), source electrodes 106 of TFT elements, a second insulation layer 107, pixel electrodes 108, counter electrodes 109 and an alignment film 110 are formed.

In manufacturing the TFT substrate 1 having such constitution, for example, first of all, a conductive film formed of an aluminum film or the like is formed on the whole surface of the insulation substrate 100, and the conductive film is etched so as to form the scanning signal lines 101 and the holding capacitance lines 103.

Next, on the whole surface of the insulation substrate 100 on which the scanning signal lines 101 and the holding capacitance lines 103 are formed, for example, a silicon oxide film or a silicon nitride film is formed thus forming the first insulation layer 104. Although a surface of the first insulation layer 104 (a surface on which the semiconductor layers 105, the video signal lines 102 and the like are formed) is made flat in the cross-sectional constitutions shown in FIG. 2B and FIG. 2C, the present invention is not limited to such constitution, and stepped portions (unevenness) may be formed on the surface of the first insulation layer 104.

Next, on the surface of the first insulation layer 104, the semiconductor layers 105 of the TFT elements, the video signal lines 102 including the drain electrodes of the TFT elements and the source electrodes 106 of the TFT elements are formed. In forming the semiconductor layers 105, the video signal lines 102 including the drain electrodes and the source electrodes 106, for example, first of all, a first semiconductor film which is used for forming active layers of the semiconductor layers 105 and a second semiconductor film which is used for forming the source regions and the drain regions are formed, and these semiconductor films are etched to form a plurality of island-shaped semiconductor layers. Next, a conductive film formed of an aluminum film or the like is formed on the whole surface of the first insulation layer 104, and the conductive film is etched so as to form the video signal lines 102 including the drain electrodes and the source electrodes 106. Here, the source electrodes 106 and the drain electrodes portions of the video signal lines 102 are respectively formed such that a portion of these parts get over the above-mentioned island-shaped semiconductor layers. Next, using the drain electrodes and the source electrodes 106 as masks, the second semiconductor layer is etched thus separating the second semiconductor layers of the above-mentioned respective island-shaped semiconductor layers into source regions and drain regions.

Next, on the whole surface of the first insulation layer 104 on which the semiconductor layers 105, the video signal lines 102 and the source electrodes 106 are formed, for example, an insulation film formed of a silicon nitride film or the like is formed thus forming a second insulation layer 107. Thereafter, through holes TH1, TH2 are formed. Here, although a surface of the second insulation layer 107 (a surface on which the pixel electrodes 108, the counter electrodes 109 and the like are formed) is made flat in the cross-sectional constitutions shown in FIG. 2B and FIG. 2C, the present invention is not limited to such constitution and stepped portions (unevenness) may be formed on the surface of the second insulation layer 107. Further, the second insulation layer 107 may be formed using one kind of insulation film or may be formed by stacking two or more kinds of insulation films.

Next, a transparent conductive film made of ITO or the like, for example, may be formed on the whole surface of the second insulation layer 107 and the through holes TH1, TH2, and the conductive film is etched so as to form the pixel electrodes 108 and the counter electrodes 109. Here, the pixel electrode 108 is electrically connected with the source electrode 106 via the through hole TH1, while the counter electrode 109 is electrically connected with the holding capacitance lines 103 via the through hole TH2.

Finally, the alignment film 110 is formed on a surface of the second insulation layer 107 on which the pixel electrodes 108 and the counter electrodes 109 are formed.

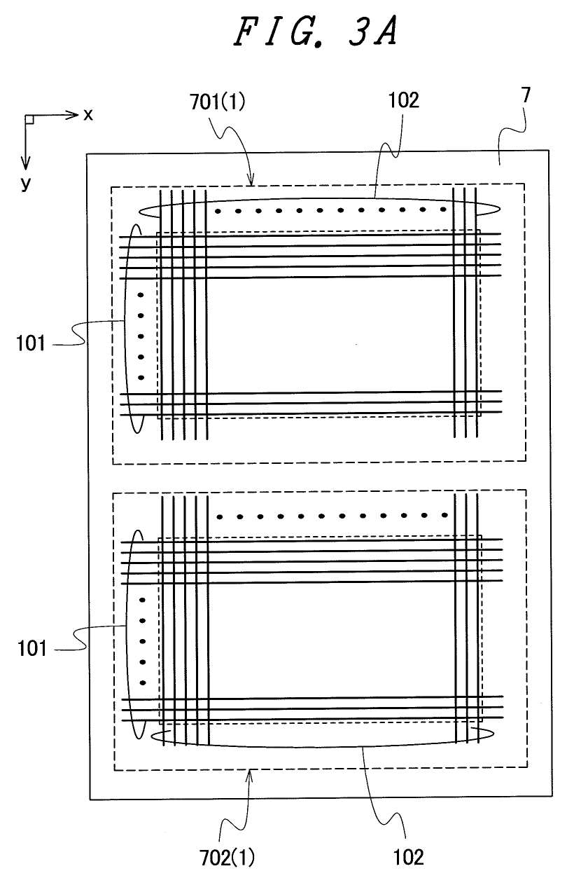

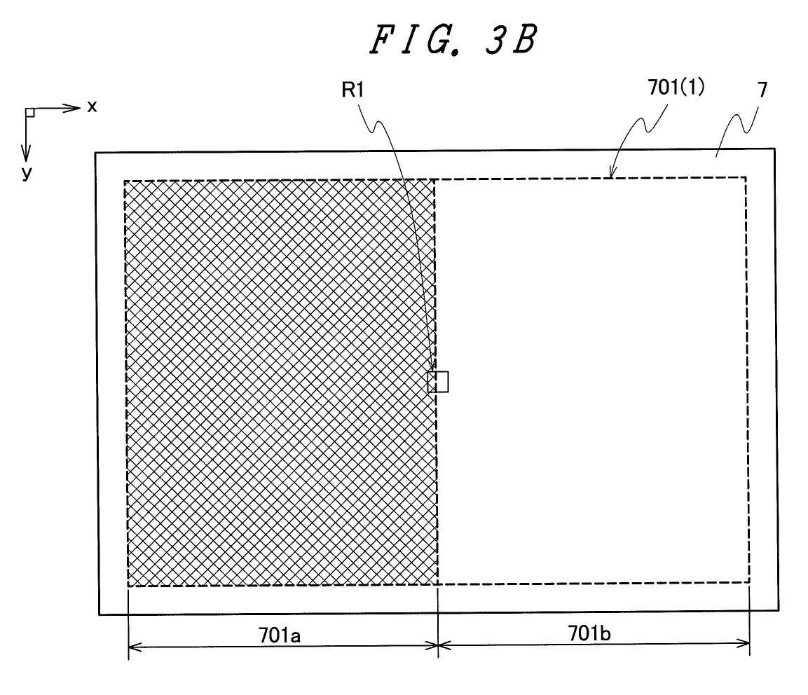

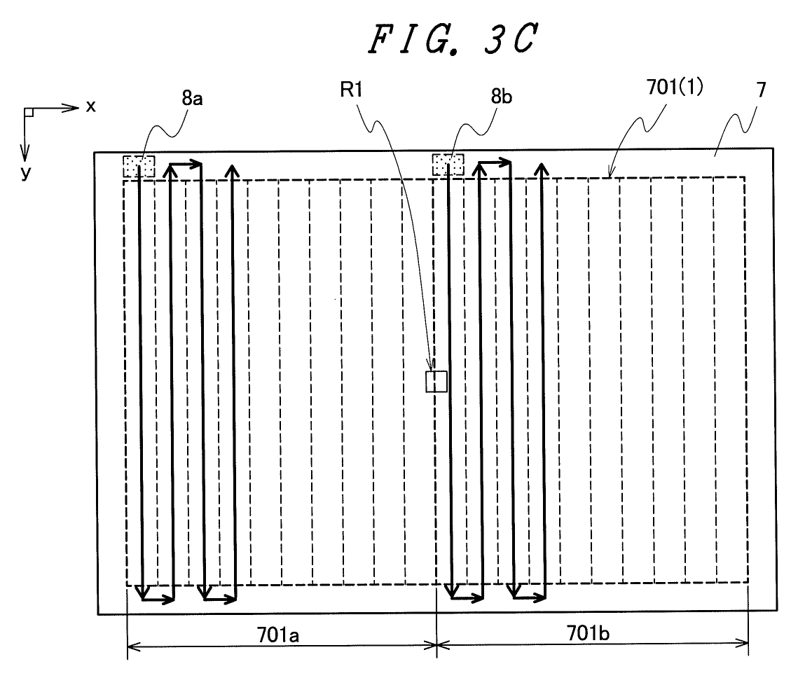

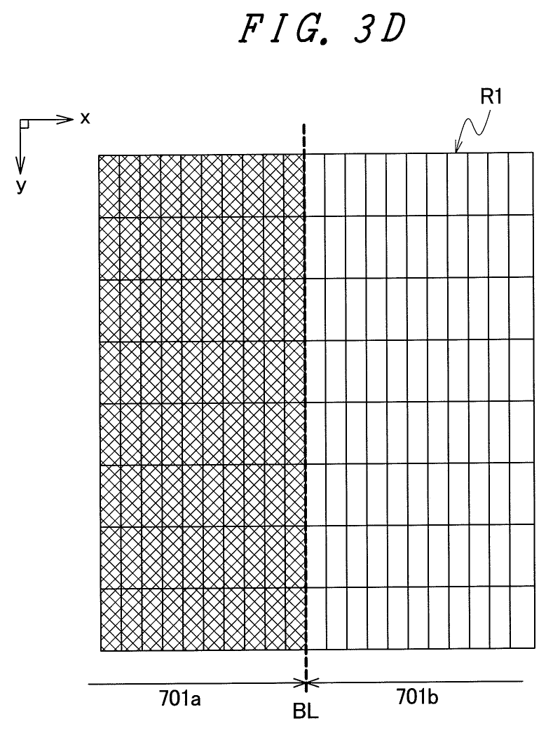

FIG. 3A to FIG. 3D are schematic views for explaining one example of a conventional manufacturing method of a TFT substrate 1 used in a liquid crystal display panel, and examples of drawbacks that the manufacturing method possesses.

FIG. 3A is a schematic plan view showing one example of the manufacturing method of the TFT substrate for simultaneously manufacturing two TFT substrates. FIG. 3B is a schematic plan view showing one example of a conventional exposure method applied to one region 701 shown in FIG. 3A. FIG. 3C is a schematic plan view showing another example of the conventional exposure method applied to one region 701 shown in FIG. 3A. FIG. 3D is an enlarged plan view of a region R1 shown in FIG. 3B and FIG. 3C.

Here, the x direction and the y direction shown in FIG. 3A to FIG. 3D are respectively directed in the same directions as the x direction and the y direction shown in FIG. 1A.

Currently, in manufacturing the TFT substrate 1 used in the liquid crystal display panel, for example, the TFT substrate 1 is manufactured by a so-called multiple-substrate simultaneous manufacturing method which can form a plurality of TFT substrates 1 at a time using one large-area glass substrate (mother glass 7).

In the manufacturing method which forms two TFT substrates 1 at a time using one mother glass 7 (so-called two-substrate simultaneous manufacturing method), for example, as shown in FIG. 3A, a circuit which functions as the TFT substrate 1 is formed in two respective regions 701, 702 of the mother glass 7. Then, in accordance with the above-mentioned steps, the scanning signal lines 101, the video signal lines 102, the TFT elements, the pixel electrodes 108 and the like are formed in respective regions and, thereafter, the respective regions 701, 702 are cut out from the mother glass 7 thus acquiring two TFT substrates 1 at a time.

In the two-substrate simultaneous manufacturing method, for example, the conductive film or the like for forming the scanning signal lines 101 in the respective regions are formed over the whole surface of the mother glass 7. Further, masks used for etching the conductive film (etching resists) are formed by forming a photosensitive resist on the whole surface of the conductive film and by exposing and developing the photosensitive resist.

Here, the exposure of the photosensitive resist may be performed by determining the region to be cut out (region 701, for example) as one sheet of TFT substrate 1, and by exposing the photosensitive resist for every cutout region, for example.

In exposing the photosensitive resist using the photo mask, for example, a photo mask in which a mask pattern corresponding to a resist pattern formed in one region to be cut out as one sheet of TFT substrate 1 and a periphery of the region is used. Then, first of all, one region 701 out of two regions 701, 702 of the mother glass and a periphery of the region 701 are exposed and, subsequently, another region 702 and a periphery of another region 702 are exposed.

Here, when the TFT substrate 1 to be formed is a TFT substrate used in a large-screen liquid crystal television receiver set (liquid crystal display panel), for example, in exposing the whole one region 701 at a time in the exposure step for one time, a photo mask to be used in the step becomes extremely large. Accordingly, the manufacture and the management of the photo mask become extremely difficult thus pushing up a manufacturing cost of the TFT substrate 1.

In view of the above-mentioned drawback, when the TFT substrate 1 to be formed is a TFT substrate used in a large-screen liquid crystal television receiver set (liquid crystal display panel), in exposing the whole one region 701 using the photo mask, for example, as shown in FIG. 3B, the above-mentioned one region 701 is divided into two exposure regions (first exposure region 701a and the second exposure region 701b) and the respective exposure regions 701a, 701b are individually exposed thus exposing the whole one region 701. An exposure device used in such exposure includes, for example, a first photo mask used for the exposure of the first exposure region 701a and a second photo mask used for exposure of the second exposure region 701b. Then, for example, first of all, a light source of the exposure device is arranged at a position where the first exposure region 701a can be exposed thus exposing the first exposure region 701a using the first photo mask. Thereafter, for example, the light source is moved to a position where the second exposure region 701b can be exposed and, at the same time, the first photo mask is exchanged with the second photo mask, and the second exposure region 701b is exposed using the second photo mask.

Due to such an exposure method, although the number of photo masks used in the exposure for one time is increased, a size of one photo mask can be reduced compared to the size of one photo mask for exposing one region 701 and hence, the manufacture and the management of the respective photo masks become easy thus suppressing the increase of a manufacturing cost of the TFT substrate 1.

Further, recently, as a manufacturing method of a TFT substrate 1, there has been also proposed a method which exposes by a direct-drawing exposure method (direct exposure method) which uses no photomask. In the direct-drawing exposure method, for example, a region where a photosensitive resist is exposed designated in the above-mentioned one region (region 701, for example) based on layout data (numerical value data) prepared by a CAD or the like, and the whole one region is exposed by scanning a light of an exposure device, for example. Here, the exposure device includes a moving means which moves relative positions of the light source and the insulation substrate, and a control means which controls radiation/non-radiation of light from the light source based on preliminarily prepared numerical value data.

Here, when the TFT substrate 1 to be formed is a TFT substrate used in a large-screen liquid crystal television receiver set (liquid crystal display panel), for example, when the above-mentioned light source of the exposure device is one, time necessary for exposing the whole one region 701 becomes extremely prolonged. Accordingly, manufacturing efficiency of the TFT substrate 1 is lowered thus pushing up a manufacturing cost of the TFT substrate 1.

Accordingly, when the TFT substrate 1 to be formed is a TFT substrate used in a large-screen liquid crystal television receiver set (liquid crystal display panel), in exposing the whole one region 701 by the direct-drawing exposure method, it is desirable that, for example, as shown in FIG. 3C, one region 701 is divided into two exposure regions (a first exposure region 701a and a second exposure region 701b), two independent light sources (a first light source 8a and a second light source 8b) are prepared, and the first exposure region 701a and the second exposure region 701b are exposed in parallel. That is, the first exposure region 701a is exposed by the first light source 8a, and the second exposure region 701b is exposed by the second light source 8b. Due to such an exposure method, time necessary for exposing the whole one region 701 can be approximately halved compared to a case in which the whole one region 701 is exposed by one light source.

Here, in the example shown in FIG. 3C, one region 701 is divided into two exposure regions. However, this technique is not limited to such constitution, and by dividing one region into three or more exposure regions and by exposing the respective exposure regions in parallel, time necessary for exposing the whole one region can be further shortened.

However, when one region 701 is divided into the first exposure region 701a and the second exposure region 701b and the respective exposure regions are individually exposed, as a matter of course, for example, as shown in FIG. 3D, the first exposure region 701a on a left side of a boundary BL and the second exposure region 701b on a right side of the boundary are exposed using different photo masks or different light sources. FIG. 3D is an enlarged plan view of a region R1 shown in FIG. 3B and FIG. 3C, and one square indicates one pixel.

Here, for example, in exposing the first exposure region 701a using the first photo mask and, subsequently, exposing the second exposure region 701b using the second photo mask, a mechanical error occurs at the time of performing alignment by exchanging the photo mask, for example, misalignment (positional displacement) occurs in a resist pattern to be formed in a boundary portion between the first exposure region 701a and the second exposure region 701b or a size of the resist pattern is largely changed.

Further, for example, also in exposing the respective exposure regions 701a, 701b by the above-mentioned two independent light sources, for example, due to mechanical errors or the like of control mechanism of respective light sources, misalignment (positional displacement) occurs in a resist pattern to be formed in a boundary portion between the first exposure region 701a and the second exposure region 701b or a size of the resist pattern is largely changed.

That is, when one region 701 is divided into the first exposure region 701a and the second exposure region 701b and the respective exposure regions 701a, 701b are individually exposed, for example, there may be a case that the difference between a width (size in the x direction) of the video signal line 102 formed on a left side of the boundary line BL between two exposure regions (first exposure region 701a) and a width of the video signal line 102 formed on a right side of the boundary line BL (second exposure region 701b) becomes large. Further, when the TFT substrate 1 having the constitution shown in any one of FIG. 2A to FIG. 2C is manufactured, for example, there may be a case that a gap between the pixel electrode 108 and the counter electrode 109 in the pixel formed on a left side of the boundary line BL and a gap between the pixel electrode 108 and the counter electrode 109 in the pixel formed on a right side of the boundary line BL becomes large.

Further, when one region 701 is divided into the first exposure region 701a and the second exposure region 701b and the respective exposure regions 701a, 701b are individually exposed, in the conventional method, the boundary line BL in the respective exposure steps which are performed a plurality of times during a process for manufacturing one sheet of TFT substrate 1 is set to always pass the same position, for example.

Accordingly, in the respective exposure steps of the photosensitive resist which are performed a plurality of times in the process for manufacturing the TFT substrate 1, when one region 701 is divided into the first exposure region 701a and the second exposure region 701b and the respective exposure regions 701a, 701b are individually exposed, for example, a liquid crystal display device having a liquid crystal display panel which uses the TFT substrate 1 acquired in the above-mentioned manner is liable to generate image quality irregularities at a portion of the boundary BL between two exposure regions 701a, 701b.

The present invention has been made in view of the above-mentioned drawbacks, and provides a manufacturing method of a TFT substrate (liquid crystal display device) which can suppress the generation of image quality irregularities at the portion of the boundary BL between the above-mentioned two exposure regions 701a, 701b in a liquid crystal display device having a liquid crystal display panel using the TFT substrate 1 in manufacturing the TFT substrate 1 by a method in which one region 701 is divided into the first exposure region 701a and the second exposure region 701b and the respective exposure regions 701a, 701b are individually exposed in the respective exposure steps of a photosensitive resist which is performed a plurality of times in a process for manufacturing the TFT substrate 1.

### Embodiment 1

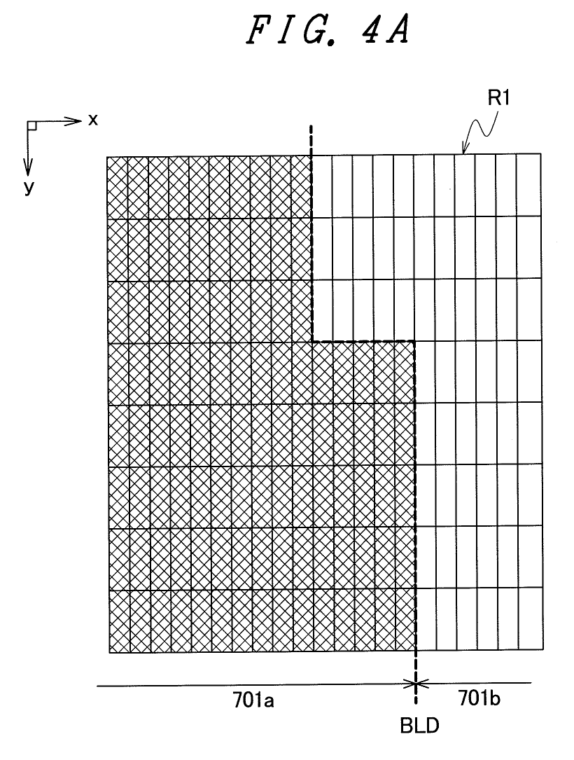

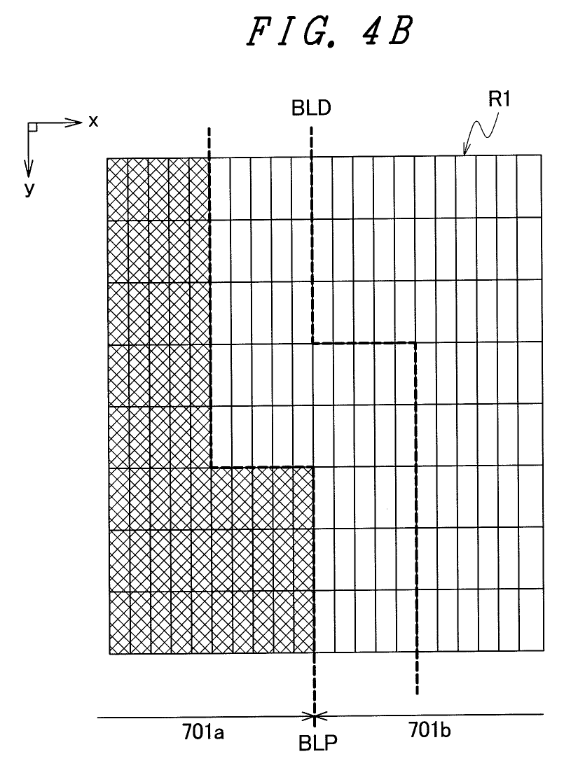

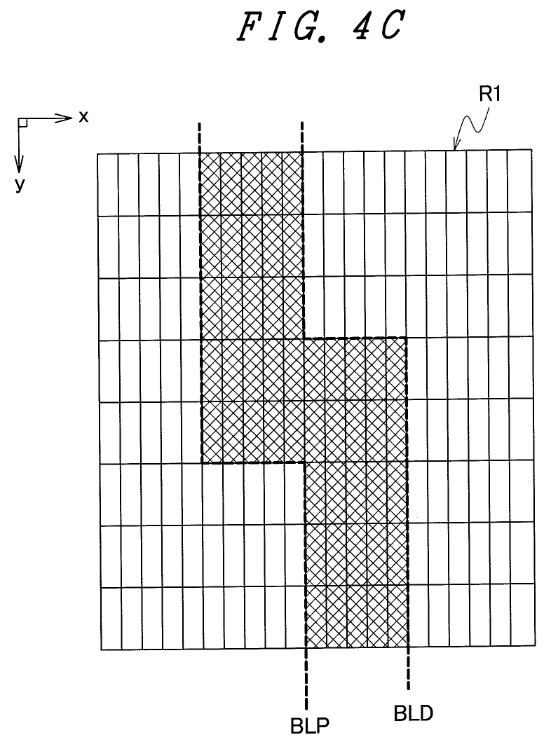

FIG. 4A to FIG. 4C are schematic views for explaining one example of a manufacturing method of a TFT substrate of the embodiment 1 according to the present invention.

FIG. 4A is a schematic plan view showing one example of an exposure method of a photosensitive resist which is performed for forming video signal lines. FIG. 4B is a schematic plan view showing one example of an exposure method of a photosensitive resist which is performed for forming pixel electrodes and counter electrodes. FIG. 4C is a schematic plan view for explaining the manner of operation and advantageous effects of the exposure method of the embodiment 1.

Here, FIG. 4A to FIG. 4C show the same region as the region shown in FIG. 3D. That is, one square indicates one pixel. Further, the x direction and the y direction shown in FIG. 4A to FIG. 4C are equal to the x direction and the y direction adopted in FIG. 3D respectively.

The manufacturing method of the TFT substrate 1 of the embodiment 1 is basically equal to a conventional manufacturing method of a TFT substrate. The point which makes the manufacturing method of the TFT substrate 1 of the embodiment 1 different from the conventional manufacturing method of a TFT substrate lies in the exposure method in a step of exposing a photosensitive resist which is performed a plurality of times during a process of manufacturing one sheet of the TFT substrate 1. Further, the embodiment 1 exemplifies a case in which the photosensitive resist is exposed by the above-mentioned direct-drawing exposure method.

The exposure method of the photosensitive resist which is performed a plurality of times in the manufacturing method of the TFT substrate 1 of the embodiment 1 is substantially equal to the exposure method shown in FIG. 3C. That is, one region 701 which is cut out from a mother glass 7 as one sheet of TFT substrate is divided a first exposure region 701a and a second exposure region 701b, and two exposure regions 701a, 701b are exposed in parallel by the direct-drawing exposure method using two independent light sources 8a, 8b.

Here, the exposure of the photosensitive resist which is performed for forming the video signal lines 102 is performed, as shown in FIG. 4A, for example, by dividing one region 701 into the first exposure region 701a and the second exposure region 701b using one boundary line BLD which is constituted of a line segment which extends in the extension direction (y direction) of the video signal lines 102 and a line segment which extends in the extension direction (x direction) of the scanning signal lines 101. Here, the first exposure region 701a on a left side of the boundary line BLD is exposed by only the first light source 8a, and the second exposure region 701b on a right side of the boundary line BLD is exposed by only the second light source 8b.

Further, the exposure of the photosensitive resist for forming the pixel electrodes 108 and the counter electrodes 109 is performed, as shown in FIG. 4B, for example, by dividing one region 701 into the first exposure region 701a and the second exposure region 701b using another one boundary line BLP which is constituted of a line segment which extends in the extension direction (y direction) of the video signal lines 102 and a line segment which extends in the extension direction (x direction) of the scanning signal lines 101 but is not aligned with the boundary line BLD in exposure which is performed for forming the video signal lines 102. Here, the first exposure region 701a on a left side of the boundary line BLP is exposed by only the first light source 8a, and the second exposure region 701b on a right side of the boundary line BLP is exposed by only the second light source 8b.

Due to such exposure, with respect to a region formed between the boundary line BLD and the boundary line BLP shown in FIG. 4C, for example, the video signal lines 102 are formed with a size which reflects a resist pattern acquired by exposure using the first light source 8a, and the pixel electrodes 108 and the counter electrodes 109 are formed with a size which reflects a resist pattern acquired by exposure using the second light source 8b. With respect to a region formed on a left side of the boundary line BLP, all of the video signal lines 102, the pixel electrodes 108 and the counter electrodes 109 are formed with a size which reflects a resist pattern acquired by exposure using the first light source 8a. Further, with respect to a region formed on a right side of the boundary line BLD, all of the video signal lines 102, the pixel electrodes 108 and the counter electrodes 109 are formed with a size which reflects a resist pattern acquired by exposure using the second light source 8b.

Here, for example, when a mechanical error occurs in a control mechanism of the first light source 8a or a control mechanism of the second light source 8b in the exposure device in use, the positional displacement or the change of size of the video signal line 102 occurs on a portion of the boundary line BLD, and the positional displacement or the change of size of the pixel electrode 108 or the counter electrode 109 occurs on a portion of the boundary line BLP. Accordingly, the manufacturing method of the TFT substrate 1 of the embodiment 1 can absorb the misalignment (positional displacement) or the change of size which occurs on the boundary between the first exposure region 701a and the second exposure region 701b in steps for exposing the respective photosensitive resists in the region between two boundary lines BLD, BLP thus suppressing (decreasing) the image quality irregularities which occurs on the boundary portion between the first exposure region 701a and the second exposure region 701b.

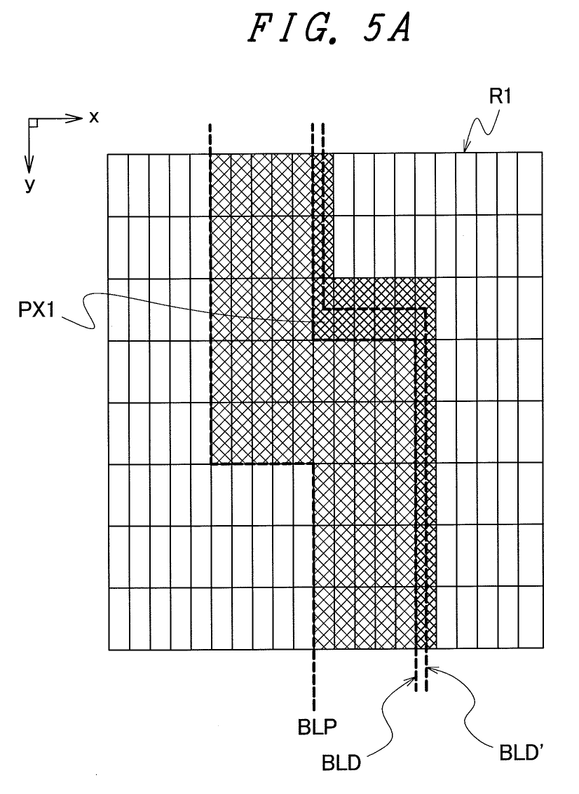

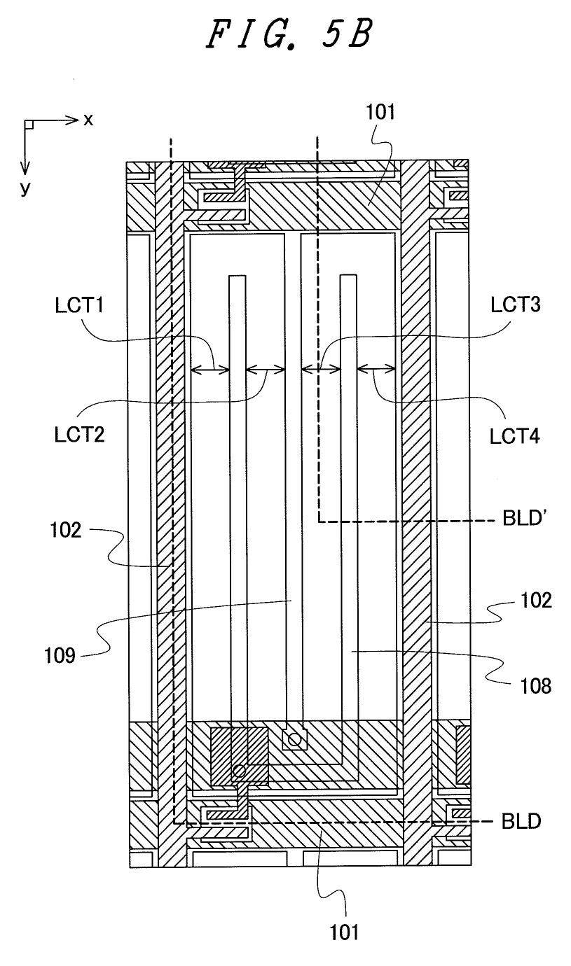

FIG. 5A and FIG. 5B are schematic views for explaining a modification of the manufacturing method of the TFT substrate 1 of the embodiment 1.

FIG. 5A is a schematic plan view showing a modification of an exposure method of a photosensitive resist which is performed for forming the pixel electrodes and the counter electrodes. FIG. 5B is a schematic plan view for explaining the manner of operation and advantageous effects of the exposure method of the modification shown in FIG. 5A.

Here, FIG. 5A shows the same region as the region shown in FIG. 4C. That is, one square indicates one pixel. Further, FIG. 5B shows one pixel PX1 shown in FIG. 5A in an enlarged manner. Still further, the x direction and the y direction in FIG. 5A and FIG. 5B are respectively equal to the x direction and the y direction adopted in FIG. 4C.

In the manufacturing method of the TFT substrate 1 of the embodiment 1, for example, as shown in FIG. 4C, by displacing the boundary line BLD between two exposure regions 701a, 701b in the exposure which is performed for forming the video signal lines 102 and the boundary line BLP between two exposure regions 701a, 701b in the exposure which is performed for forming the pixel electrodes 108 and the counter electrodes 109 from each other, the image quality irregularities which occur on the boundary portion between two exposure regions 701a, 701b can be reduced. Here, it is needless to say that the boundary line between two exposure regions 701a, 701b in respective exposure steps is not limited to the combination of the line segment which passes on the video signal lines 102 and the line segment which passes on the scanning signal lines 101 shown in FIG. 4C, and can be constituted of the combination of various line segments.

That is, among the exposures which are performed a plurality of times, in one exposure which is performed for forming the video signal lines 102, two exposure regions 701a, 701b may be formed, for example, as shown in FIG. 5A, by dividing the exposure region 701 using a boundary line BLD′ in which a line segment which extends in the extension direction (y direction) of the video signal lines 102 passes between two neighboring video signal lines 102, and a line segment which extends in the extension direction (x direction) of the scanning signal lines 101 passes between two neighboring scanning signal lines 101. Here, in FIG. 5A, the boundary line BLD shown in FIG. 4C is also indicated as the reference.

Here, to focus on one pixel PX1 shown in FIG. 5A, the boundary lines BLD, BLD′ between two exposure regions 701a, 701b in the exposure which is performed for forming the video signal lines 102 pass at positions shown in FIG. 5B, for example.

When one region 701 is divided using the boundary line BLD shown in FIG. 4C or FIG. 5A in the exposure of the photosensitive resist which is performed for forming the video signal lines 102, for example, the boundary line BLD passes the position shown in FIG. 5B, for example. Here, the line segment along the extension direction (x direction) of the scanning signal line 101 out of the boundary line BLD passes a portion of the pixel PX1 where the TFT element is formed. Accordingly, when one region 701 is divided into two exposure regions 701a, 701b using such a boundary line BLD, the drain electrode and the source electrode 106 in one TFT element in which the boundary line BLD passes are formed by etching which uses an etching resist formed by exposure using difference light sources, for example. As a result, for example, a channel length of the TFT element in which the boundary line BLD passes has a value different from a value of a channel length of the surrounding TFT element thus giving rise to high possibility that a spot defect occurs.

Accordingly, in general manufacturing method of a TFT substrate which forms the drain electrodes and the source electrodes 106 of the TFT elements together with the video signal lines 102, in the exposure of the photosensitive resist which is performed for forming the video signal lines 102, it is preferable to divide one region 701 into two exposure regions 701a, 701b using the boundary line BLD′ shown in FIG. 5A and FIG. 5B, for example. Due to such exposure, both of the drain electrode and the source electrode 106 of the TFT element which is formed in a periphery of the boundary between two exposure regions 701a, 701b are formed by etching which uses an etching resist formed by exposure using the same light source. Accordingly, for example, possibility that the channel lengths of the TFT elements assume values locally different from each other can be reduced thus reducing possibility of the occurrence of a spot defect.

However, it is preferable that the boundary line BLP between two exposure regions 701a, 701b in the exposure which is performed for forming the pixel electrodes 108 and the counter electrodes 109 is, for example, as shown in FIG. 4C and FIG. 5A, constituted such that the whole boundary line BLP is formed of only the line segment which passes a region where the video signal line 102 is formed and the line segment which passes the region where the scanning signal line 101 is formed.

When the boundary line BLP between two exposure regions 701a, 701b in the exposure which is performed for forming the pixel electrodes 108 and the counter electrodes 109 passes the position corresponding to the boundary line BLD′ shown in FIG. 5B, for example, it is considered that, out of gaps LCT1, LCT2, LCT3, LCT4 formed between the pixel electrode 108 and the counter electrode 109, for example, the gaps LCT3, LCT4 have different values with the boundary line BLP (BLD′) as a border. When portions where the size value changes discontinuously is present among the gaps LCT1, LCT2, LCT3, LCT4 between the pixel electrode and the counter electrode 109 in one pixel in this manner, there exists possibility that a defect which is referred to as stripe irregularities occur, for example.

Accordingly, it is preferable that the boundary line BLP between two exposure regions 701a, 701b in the exposure which is performed for forming the pixel electrode 108 and the counter electrode 109 passes the position where a set of the pixel electrode 108 and the counter electrode 109 falls in the common exposure region with respect to all pixels.

In this manner, by dividing the exposure region 701 using the boundary line BLD′ which does not pass the region where the TFT element is formed in the exposure which is performed for forming the video signal lines 102, and by dividing the exposure region 701 using the boundary line BLP which makes the set of the pixel electrode 108 and the counter electrode 109 fall in the common exposure region with respect to all pixels in the exposure which is performed for forming the pixel electrodes 108 and the counter electrodes 109, it is possible to reduce image quality irregularities without lowering a manufacturing yield ratio of the TFT substrate (liquid crystal display panel).

Further, in the embodiment 1, the case in which one region 701 is divided in two exposure regions 701a, 701b in the exposure step for one time is exemplified. However, it is needless to say that the present invention is not limited to such a case, and one region 701 is divided into three or more exposure regions, and each boundary portion between two neighboring exposure regions may be subject to exposure using the method explained in conjunction with the embodiment 1.

Further, in the embodiment 1, only the relationship between the boundary line BLD (BLD′) in the exposure which is performed for forming the video signal lines 102 and the boundary line BLP in the exposure which is performed for forming the pixel electrodes 108 and the counter electrodes 109 is exemplified. However, it is needless to say that a boundary line in the exposure which is performed for forming the scanning signal lines 101 or a boundary line in the exposure which is performed for forming active layers of the semiconductor layers 105 can be displaced in the same manner from the boundary line in other exposure thus suppressing image quality irregularities attributed to misalignment or a change of size.

Still further, in the embodiment 1, the case in which the exposure is performed by the direct-drawing exposure method is exemplified. However, it is needless to say that the present invention is not limited to such a case. For example, also in a case which performs exposure using a photo mask, by forming two or a plurality of photo masks used in the respective exposure steps by dividing in the same manner, it is possible to suppress (reduce) image quality irregularities attributed to misalignment (positional displacement) or change of size on a boundary portion between an exposure region which is exposed using the first photo mask and an exposure region which is exposed using the second mask.

### Embodiment 2

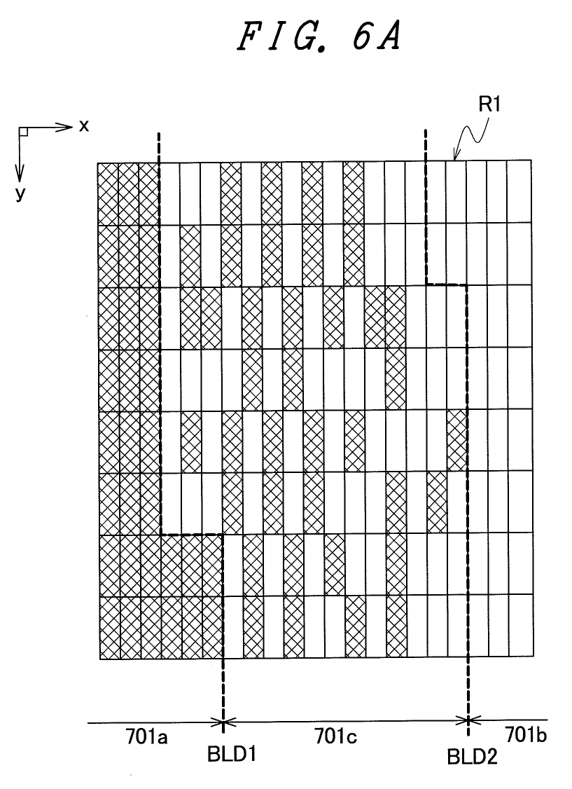

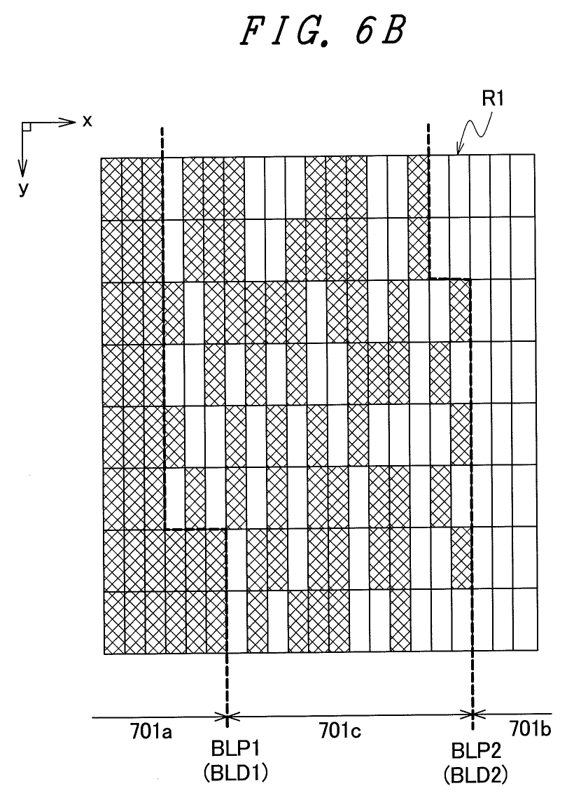

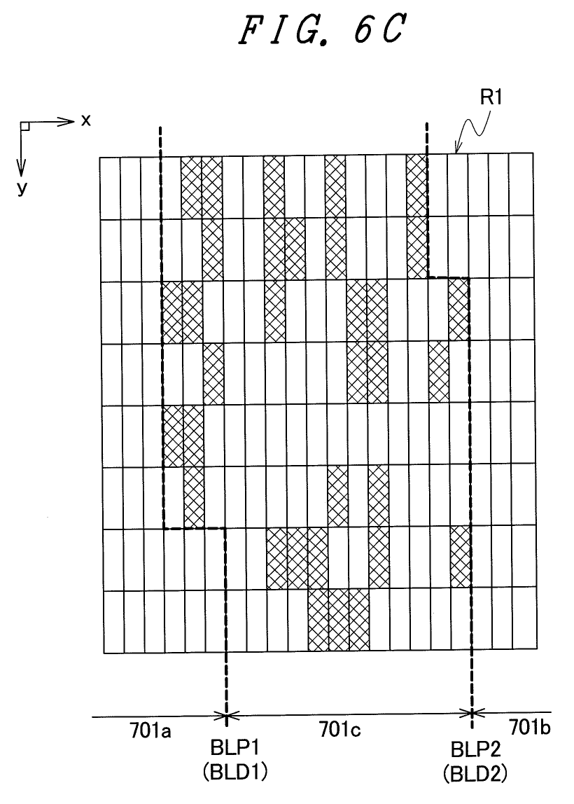

FIG. 6A to FIG. 6C are schematic views for explaining one example of a manufacturing method of a TFT substrate of the embodiment 2 according to the present invention.

FIG. 6A is a schematic plan view showing one example of an exposure method of a photosensitive resist which is performed for forming video signal lines. FIG. 6B is a schematic plan view showing one example of an exposure method of a photosensitive resist which is performed for forming pixel electrodes and counter electrodes. FIG. 6C is a schematic plan view for explaining the manner of operation and advantageous effects of the exposure method of the embodiment 2.

Here, FIG. 6A to FIG. 6C show the same region as the region shown in FIG. 3D. That is, one square indicates one pixel. Further, the x direction and the y direction shown in FIG. 6A to FIG. 6C are equal to the x direction and the y direction in FIG. 3D respectively.

The manufacturing method of the TFT substrate 1 of the embodiment 2 is basically equal to a conventional manufacturing method of a TFT substrate. The point which makes the manufacturing method of the TFT substrate 1 of the embodiment 2 different from the conventional manufacturing method of a TFT substrate and the manufacturing method of the TFT substrate of the embodiment 1 lies in the exposure method in a step of exposing a photosensitive resist which is performed a plurality of times during a process of manufacturing one sheet of the TFT substrate 1. Further, the embodiment 2 also exemplifies a case in which the photosensitive resist is exposed by the above-mentioned direct-drawing exposure method.

The exposure method of the photosensitive resist which is performed a plurality of times in the manufacturing method of the TFT substrate 1 of the embodiment 2 is substantially equal to the exposure method shown in FIG. 3C. That is, one region 701 which is cut out from a mother glass 7 as one sheet of TFT substrate is divided into the first exposure region 701a and the second exposure region 701b, and two exposure regions 701a, 701b are exposed in parallel by the direct-drawing exposure method using two independent light sources 8a, 8b.

Further, when one region 701 is exposed by two independent light sources, in the embodiment 1, as shown in FIG. 4A to FIG. 4C, for example, one region 701 is divided into two exposure regions 701a, 701b by one boundary line BLD (or boundary line BLP), and the first exposure region 701a and the second exposure region 701b in the exposure step for one time do not have the overlapping portion. To the contrary, in the embodiment 2, one region 701 is divided by a method shown in FIG. 6A to FIG. 6C, for example.

That is, according to the manufacturing method of a TFT substrate 1 of the embodiment 2, in the exposure of the photosensitive resist which is performed for forming the video signal lines 102, as shown in FIG. 6A, for example, one region 701 is divided into three exposure regions 701a, 701b, 701c by a first boundary line BLD1 and a second boundary line BLD2. Here, the first exposure region 701a on a left side of the first boundary line BLD1 is exposed by only the first light source 8a, and the second exposure region 701b on a right side of the second boundary line BLD2 is exposed by only the second light source 8b. Further, in the third exposure region 701c which is disposed between the first boundary line BLD1 and the second boundary line BLD2, for example, pixels (first small regions) which are exposed by the first light source 8a and pixels (second small regions) which are exposed by the second light source 8b are arranged in a mosaic shape (at random). Here, in FIG. 6A, the half-tone-dot-meshing pixels (squares) indicate the pixels which are exposed by the first light source 8a, and the white pixels (squares) indicate the pixels which are exposed by the second light source 8b.

Such a method for dividing the exposure region may be expressed as follows. That is, for example, in dividing one region 701 into two exposure regions 701a, 701b, such division is made such that the partial region (third exposure region 701c) where two exposure regions 701a, 701b overlap with each other is formed on a boundary portion between the first exposure region 701a and the second exposure region 701b, and the regions which are exposed by the first light source 8a and the regions which are exposed by the second light source 8b are arranged in the partial region in a mosaic shape (at random).

Further, according to the manufacturing method of a TFT substrate 1 of the embodiment 2, for example, in the exposure of the photosensitive resist which is performed for forming the pixel electrodes 108 and the counter electrodes 109, also when one region 701 is exposed by two independent light sources, one region 701 is divided into three exposure regions 701a, 701b, 701c by a first boundary line BLP1 and a second boundary line BLP2 as shown in FIG. 6B, for example. Here, the first boundary line BLP1 and the second boundary line BLP2 are respectively aligned with the first boundary line BLD1 and the second boundary line BLP2 in the exposure which is performed for forming the video signal lines 102. Further, in such an exposure operation, the first exposure region 701a on a left side of the first boundary line BLP1 is exposed by only the first light source 8a, and the second exposure region 701b on a right side of the second boundary line BLP2 is exposed by only the second light source 8b. Further, in the third exposure region 701c which is disposed between the first boundary line BLP1 and the second boundary line BLP2, pixels which are exposed by the first light source 8a and pixels which are exposed by the second light source 8b are arranged in a mosaic shape (at random). Here, in FIG. 6B, the half-tone-dot-meshing pixels (squares) indicate the pixels which are exposed by the first light source 8a, and the white pixels (squares) indicate the pixels which are exposed by the second light source 8b.

Further, the pixels which are exposed by the first light source 8a and the pixels which are exposed by the second light source 8b in the third exposure region 701c in the exposure which is performed for forming the pixel electrodes 108 and the counter electrodes 109 are arranged to have the arrangement different from the arrangement of the pixels at the time of forming the video signal lines 102.

Due to such constitution, a combined pattern of light sources for exposing the respective pixels in the region R1 may become a pattern shown in FIG. 6C, for example. In FIG. 6C, the half-tone-dot-meshing pixels (squares) are pixels where the light source which is used for forming the video signal lines 102 and the light source which is used for forming the pixel electrodes 108 and the counter electrodes 109 differ from each other, while the white pixels (squares) are pixels where the light source which is used for forming the video signal lines 102 and the light source which is used for forming the pixel electrodes 108 and the counter electrodes 109 are equal to each other.

That is, according to the manufacturing method of the TFT substrate 1 of the embodiment 2, between the first exposure region 701a consisting of the pixels where both of the light source which is used for forming the video signal lines 102 and the light source which is used for forming the pixel electrodes 108 and the counter electrodes 109 are formed of the first light source 8a and the second exposure region 701b consisting of the pixels where both of the light source which is used for forming the video signal lines 102 and the light source which is used for forming the pixel electrodes and the counter electrodes are formed of the second light source 8b, there is provided the third exposure region 701c (partial region) consisting of pixels where the light source which is used for forming the video signal lines 102 and the light source which is used for forming the pixel electrodes 108 and the counter electrodes 109 are equal to each other and the pixels where the light source which is used for forming the video signal lines 102 and the light source which is used for forming the pixel electrodes 108 and the counter electrodes 109 differ from each other.

Here, four kinds of pixels are arranged in the third exposure region 701c at random. That is, in the third exposure region 701c, the pixels where both of the light source which is used for forming the video signal lines 102 and the light source which is used for forming the pixel electrodes 108 and the counter electrodes 109 are formed of the first light source 8a, the pixels where both of the light source which is used for forming the video signal lines 102 and the light source which is used for forming the pixel electrodes 108 and the counter electrodes 109 are formed of the second light source 8b, the pixels where the light source which is used for forming the video signal lines 102 is formed of the first light source 8a and the light source which is used for forming the pixel electrodes 108 and the counter electrodes 109 is formed of the second light source 8b, and the pixels where the light source which is used for forming the video signal lines 102 is formed of the second light source 8b and the light source which is used for forming the pixel electrodes 108 and the counter electrodes 109 is formed of the first light source 8a are arranged at random.

That is, according to the manufacturing method of the TFT substrate 1 of the embodiment 2, by providing the third exposure region 701c (partial region) which is exposed by the above-mentioned method between the first exposure region 701a which is exposed by only the first light source 8a and the second exposure region 701b which is exposed by only the second light source 8b, the misalignment (positional displacement) or the change of size which occurs on the boundary portion between the first exposure region 701a and the second exposure region 701b can be absorbed thus suppressing (decreasing) the image quality irregularities.

Further, in the embodiment 2, the first boundary line BLD1 and the second boundary line BLD2 at the time of forming the video signal lines 102 and the first boundary line BLP1 and the second boundary line BLP2 at the time of forming the pixel electrodes 108 and the counter electrodes 109 are respectively aligned with each other. However, the present invention is not limited to such constitution. That is, the first boundary line BLD1 and the second boundary line BLD2 may have positions thereof displaced from the first boundary line BLP1 and the second boundary line BLP2 respectively or may have positions thereof partially aligned with the first boundary line BLP1 and the second boundary line BLP2 respectively.

Further, in the embodiment 2, the case in which the exposure is performed by preparing two light sources for one region 701 in the exposure step for one time is exemplified. However, it is needless to say that the present invention is not limited to such a case, and three or more light sources are prepared for one region 701, and a region between an exposure region which is exposed by only one light source and an exposure region which is exposed by only another one light source may be exposed by the method explained in conjunction with the embodiment 2.

Further, in the embodiment 2, only the relationship between the exposure which is performed for forming the video signal lines 102 and the exposure which is performed for forming the pixel electrodes 108 and the counter electrodes 109 is exemplified. However, it is needless to say that the exposure which is performed for forming the scanning signal lines 101 or the exposure which is performed for forming active layers of the semiconductor layers 105 is also performed by a method explained in conjunction with the embodiment 2 thus suppressing image quality irregularities attributed to misalignment or change of size.

Still further, in the embodiment 2, the case in which the exposure is performed by the direct-drawing exposure method is exemplified. However, it is needless to say that the present invention is not limited to such a case. For example, also in a case which performs exposure using a photo mask, by forming two or a plurality of photo masks used in the respective exposure steps by dividing in the same manner, it is possible to suppress (reduce) image quality irregularities attributed to misalignment (positional displacement) or change of size on a boundary portion between an exposure region which is exposed using the first photo mask and an exposure region which is exposed using the second mask.

### Embodiment 3

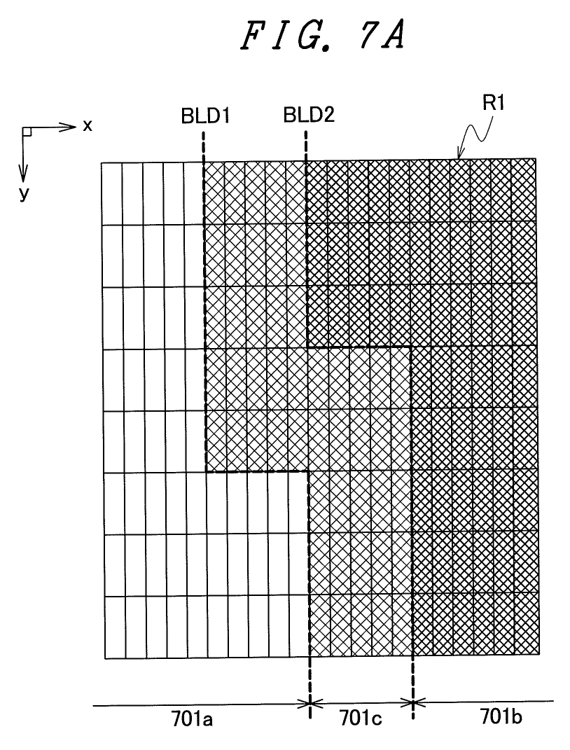

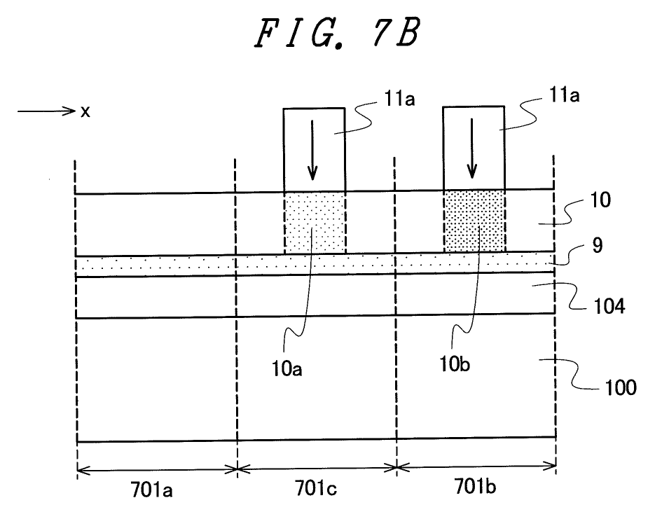

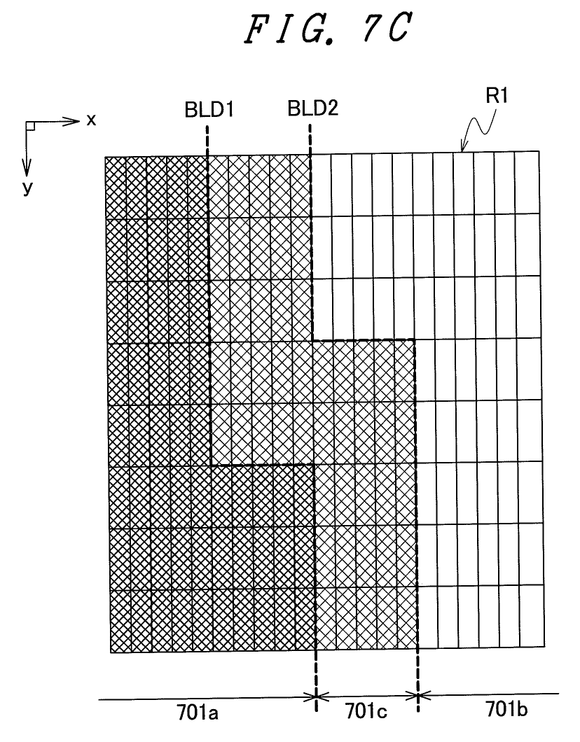

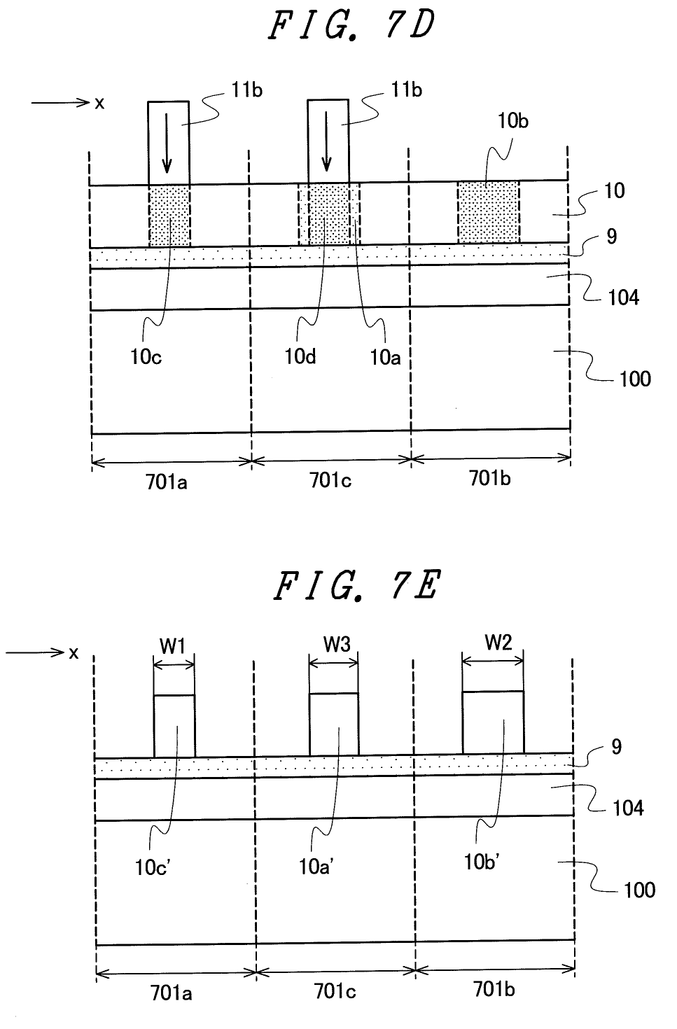

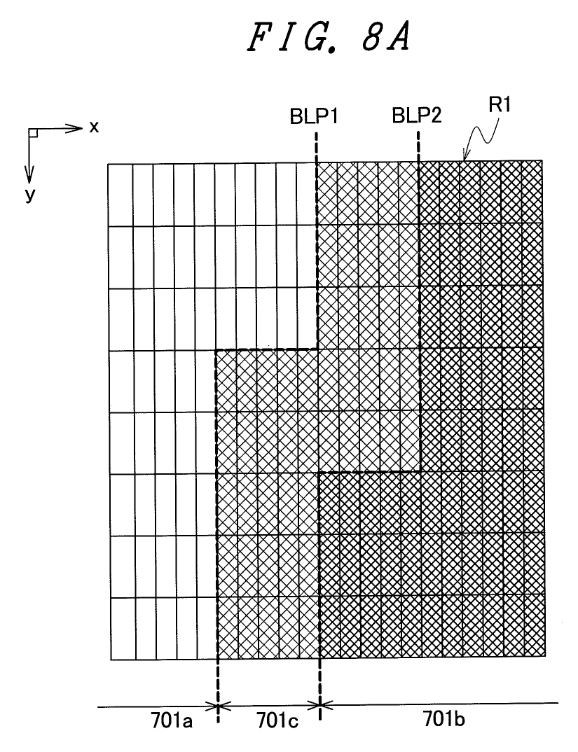

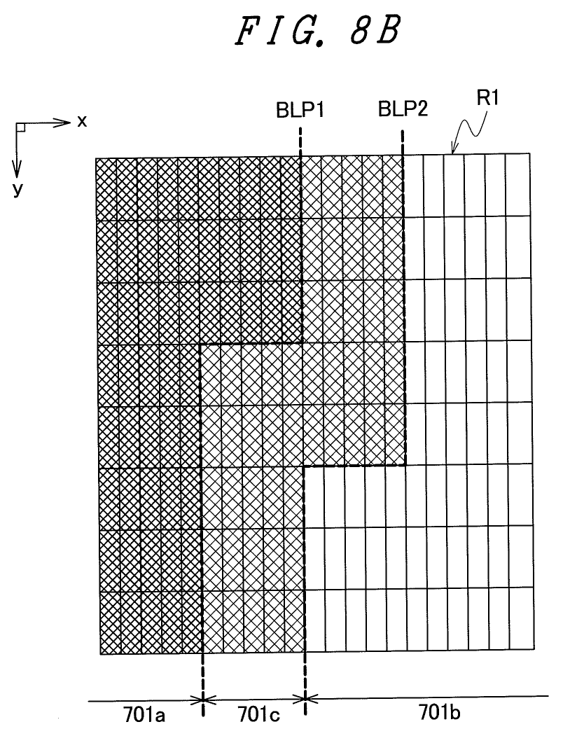

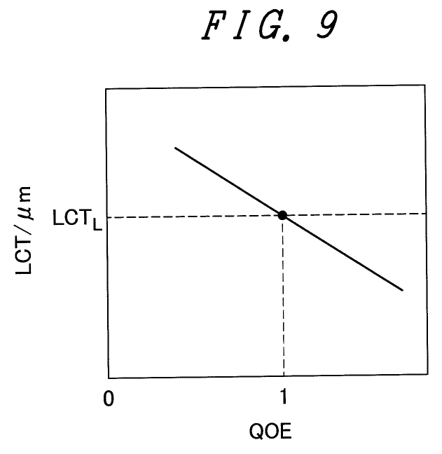

FIG. 7A to FIG. 7E, FIG. 8A and FIG. 8B are schematic views for explaining one example of a manufacturing method of a TFT substrate of the embodiment 3 according to the present invention.

FIG. 7A is a schematic plan view showing one example of an exposure method using a second light source which is performed for forming video signal lines. FIG. 7B is a schematic cross-sectional view showing one example of respective photosensitive patterns in a first exposure region, a second exposure region and a third exposure region shown in FIG. 7A. FIG. 7C is a schematic plan view showing one example of an exposure method using a first light source which is performed for forming video signal lines. FIG. 7D is a schematic cross-sectional view showing one example of respective photosensitive patterns in the first exposure region, the second exposure region and the third exposure region shown in FIG. 7C. FIG. 7E is a schematic cross-sectional view showing one example of cross-sectional shapes of resists respectively formed in the first exposure region, the second exposure region and the third exposure region.

FIG. 8A is a schematic plan view showing one example of an exposure method using a second light source which is performed for forming pixel electrodes and counter electrodes. FIG. 8B is a schematic plan view showing one example of an exposure method using a first light source which is performed for forming pixel electrodes and counter electrodes.

Here, FIG. 7A, FIG. 7C, FIG. 8A and FIG. 8B show the same region as the region shown in FIG. 3D. That is, one square indicates one pixel. Further, the x direction and the y direction shown in FIG. 7A, FIG. 7C, FIG. 8A and FIG. 8B are equal to the x direction and the y direction in FIG. 3D respectively.

According to the manufacturing method of the TFT substrate 1 of the embodiment 3, in exposing one region 701 using two independent light sources, using the method substantially equal to the method explained in conjunction with the embodiment 2, one region 701 is divided into the first exposure region 701a, the second exposure region 701b and the third exposure region 701c (partial region where the first exposure region 701a and the second exposure region 701b overlap with each other), and the first exposure region 701a is exposed by only the first light source 8a and the second exposure region 701b is exposed by only the second light source 8b.

Further, according to the manufacturing method of a TFT substrate 1 of the embodiment 3, the third exposure region 701c (partial region) is subject to the multiple exposure by the first light source 8a and the second light source 8b.

Such a method of forming the exposure regions by division and exposing the exposure regions may be also expressed as follows. That is, for example, in dividing one region 701 into two exposure regions 701a, 701b, such division is made such that the partial region (third exposure region 701c) where two exposure regions 701a, 701b overlap with each other is formed on a boundary portion between the first exposure region 701a and the second exposure region 701b, and the partial region is subject to multiple exposure by the first light source 8a and the second light source 8b.

That is, according to the manufacturing method of a TFT substrate 1 of the embodiment 3, for example, in the exposure which is performed for forming the video signal lines 102, one region 701 is, as shown in FIG. 7A, for example, divided into the first exposure region 701a, the second exposure region 701b and the third exposure region 701c by a first boundary line BLD1 and a second boundary line BLD2. In such an exposure operation, the first exposure region 701a on a left side of the first boundary line BLD1 is exposed by only the first light source 8a, and the second exposure region 701b on a right side of the second boundary line BLD2 is exposed by only the second light source 8b.

Further, in performing the exposure in accordance with steps shown in FIG. 3C by the direct-drawing exposure method, in the region R1, the exposure by the second light source 8b is firstly performed. Here, the exposure by the second light source 8b is performed such that, for example, as shown in FIG. 7A, the exposure is started with the exposure of the third exposure region 701c and, subsequently, the exposure of the second exposure region 701b is performed. In FIG. 7A, the thin-half-tone-dot-meshing pixels (squares) are pixels which are exposed with an exposure quantity approximately half of the exposure quantity necessary for completely exposing the photosensitive resist, and the thick-half-tone-dot-meshing pixels (squares) are pixels which are exposed with an exposure quantity necessary for completely exposing the photosensitive resist.

That is, the exposure of the third exposure region 701c by the second light source 8b is performed with the exposure quantity approximately half of the exposure quantity necessary for completely exposing the photosensitive resist, for example. Further, the exposure of the second exposure region 701b by the second light source 8b is performed with the exposure quantity necessary for completely exposing the photosensitive resist. Due to such an exposure operation, in the region R1 shown in FIG. 7A, an exposure pattern of the photosensitive resist in the first exposure region 701a, an exposure pattern of the photosensitive resist in the second exposure region 701b and an exposure pattern of the photosensitive resist in the third exposure region 701c are set as shown in FIG. 7B, for example. In FIG. 7B, numeral 100 indicates an insulation substrate, numeral 104 indicates a first insulation layer, numeral 9 indicates a conductive film for forming video signal lines, numeral 10 indicates the photosensitive resist, and numeral 11a indicates light from the second light source 8b. Further, in FIG. 7B, the region 10a is an incompletely exposed region, and a region 10b is a completely exposed region.

Here, the exposure by the first light source 8a is performed such that the exposure is started with the exposure of the first exposure region 701a and, for example, as shown in FIG. 7C, the exposure of the third exposure region 701c is performed lastly. In FIG. 7C, the thin-half-tone-dot-meshing pixels (squares) are pixels which are exposed with an exposure quantity approximately half of the exposure quantity necessary for completely exposing the photosensitive resist, and the thick-half-tone-dot-meshing pixels (squares) are pixels which are exposed with an exposure quantity necessary for completely exposing the photosensitive resist.

That is, the exposure of the first exposure region 701a by the first light source 8a is performed with the exposure quantity necessary for completely exposing the photosensitive resist. Further, the exposure of the third exposure region 701c by the first light source 8a is performed with the exposure quantity approximately half of the exposure quantity necessary for completely exposing the photosensitive resist, for example. Due to such an exposure operation, in the region R1 shown in FIG. 7C, an exposure pattern of the photosensitive resist in the first exposure region 701a, an exposure pattern of the photosensitive resist in the second exposure region 701b and an exposure pattern of the photosensitive resist in the third exposure region 701c are set as shown in FIG. 7D, for example. In FIG. 7D, numeral 100 indicates an insulation substrate, numeral 104 indicates a first insulation layer, numeral 9 indicates a conductive film for forming video signal lines, numeral 10 indicates the photosensitive resist, and numeral 11b indicates light from the first light source 8a. Further, regions 10a, 10c, 10d shown in FIG. 7D are completely exposed regions, and the region 10b is an incompletely exposed region.

That is, in the third exposure region 701c, only the region 10d to which both of light 11b from the second light source 8b and light 11a from the first light source 8a are radiated assumes the completely exposed state. Accordingly, for example, as shown in FIG. 7B and FIG. 7D, when the region to which light 11b from the second light source 8b is radiated is narrower than the region to which light 11b from the first light source 8a, in the third exposure region 701c, the incompletely exposed region 10a exists outside the completely exposed region 10d.

Here, when the photosensitive resist 10 which is exposed as shown in FIG. 7D is developed, for example, as shown in FIG. 7E, a width W3 of a resist 10a′ formed in the third exposure region 701c assumes a value between a width W1 of a resist 10c′ formed in the first exposure region 701a and a width W2 of a resist 10b′ formed in the second exposure region 701b. Accordingly, when the conductive film 9 is etched by using the resists 10a′, 10b′, 10c′ as masks so as to form video signal lines 102, a width of the video signal line 102 formed in the third exposure region 701c between the first boundary line BLD1 and the second boundary line BLD2 assumes a value between a width of the video signal line 102 formed in the first exposure region 701a and a width of the video signal line 102 formed in the second exposure region 701b.

Further, also in the exposure which is performed for forming the pixel electrodes 108 and the counter electrodes 109, one region 701 is, as shown in FIG. 8A, for example, divided into the first exposure region 701a, the second exposure region 701b and the third exposure region 701c (partial region where the first exposure region 701a and the second exposure region 701b overlap with each other) by a first boundary line BLP1 and a second boundary line BLP2. In such an exposure operation, the first exposure region 701a on a left side of the first boundary line BLP1 is exposed by only the first light source 8a, and the second exposure region 701b is exposed by only the second light source 8b.

Here, the exposure by the second light source 8b is performed such that, for example, as shown in FIG. 8A, the exposure is started with the exposure of the third exposure region 701c and, subsequently, the exposure of the second exposure region 701b is performed. In FIG. 8A, the thin-half-tone-dot-meshing pixels (squares) are pixels which are exposed with an exposure quantity approximately half of the exposure quantity necessary for completely exposing the photosensitive resist, and the thick-half-tone-dot-meshing pixels (squares) are pixels which are exposed with an exposure quantity necessary for completely exposing the photosensitive resist.

That is, the exposure of the third exposure region 701c by the second light source 8b is performed with the exposure quantity approximately half of the exposure quantity necessary for completely exposing the photosensitive resist, for example. Further, the exposure of the second exposure region 701b by the second light source 8b is performed with the exposure quantity necessary for completely exposing the photosensitive resist.

Here, the exposure by the first light source 8a is performed such that the exposure is started with the exposure of the first exposure region 701a and, for example, as shown in FIG. 8B, the exposure of the third exposure region 701c is performed lastly. In FIG. 8B, the thin-half-tone-dot-meshing pixels (squares) are pixels which are exposed with an exposure quantity approximately half of the exposure quantity necessary for completely exposing the photosensitive resist, and the thick-half-tone-dot-meshing pixels (squares) are pixels which are exposed with an exposure quantity necessary for completely exposing the photosensitive resist.

That is, the exposure of the first exposure region 701a by the first light source 8a is performed with the exposure quantity necessary for completely exposing the photosensitive resist. Further, the exposure of the third exposure region 701c by the first light source 8a is performed with the exposure quantity approximately half of the exposure quantity necessary for completely exposing the photosensitive resist, for example.

When the conductive film (for example, the ITO film) is etched using the etching resists acquired by exposing and developing in such a manner as masks, a gap between the pixel electrode 108 and the counter electrode 109 formed in the third exposure region 701c assumes a value between a gap between the pixel electrode 108 and the counter electrode 109 formed in the first exposure region 701a and a gap between the pixel electrode 108 and the counter electrode 109 formed in the second exposure region 701b.

That is, according to the manufacturing method of the TFT substrate 1 of the embodiment 3, by providing the third exposure region 701c (partial region) which is subject to the multiple exposure by the above-mentioned method between the first exposure region 701a which is exposed by only the first light source 8a and the second exposure region 701b which is exposed by only the second light source 8b, the misalignment (positional displacement) or the change of size which occurs on the boundary portion between the first exposure region 701a and the second exposure region 701b can be absorbed thus suppressing (decreasing) the image quality irregularities.

Further, in the embodiment 3, the first boundary line BLD1 and the second boundary line BLD2 at the time of forming the video signal lines 102 and the first boundary line BLP1 and the second boundary line BLP2 at the time of forming the pixel electrodes 108 and the counter electrodes 109 are not aligned with each other respectively. However, the present invention is not limited to such constitution. That is, the first boundary line BLD1 and the second boundary line BLD2 may have positions thereof completely aligned with the first boundary line BLP1 and the second boundary line BLP2 respectively or may have positions thereof partially aligned with the first boundary line BLP1 and the second boundary line BLP2 respectively.

Further, in the in the embodiment 3, the case in which the exposure is performed by preparing two light sources for one region 701 in the exposure step for one time is exemplified. However, it is needless to say that the present invention is not limited to such a case, and three or more light sources are prepared for one region 701, and a region between an exposure region which is exposed by only one light source and an exposure region which is exposed by only another one light source is exposed by the method explained in conjunction with the embodiment 3.

Further, in the embodiment 3, only the relationship between the exposure which is performed for forming the video signal lines 102 and the exposure which is performed for forming the pixel electrodes 108 and the counter electrodes 109 is exemplified. However, it is needless to say that the exposure which is performed for forming the scanning signal lines 101 or the exposure which is performed for forming active layers of the semiconductor layers 105 is also performed by a method explained in conjunction with the embodiment 3 thus suppressing image quality irregularities attributed to misalignment or change of size.

Still further, in the embodiment 3, the case in which the exposure is performed by the direct-drawing exposure method is exemplified. However, it is needless to say that the present invention is not limited to such a case. For example, also in a case which performs exposure using a photo mask, by forming two or a plurality of photo masks used in the respective exposure steps by dividing by the same method, it is possible to suppress (reduce) image quality irregularities attributed to misalignment (positional displacement) or change of size on a boundary portion between an exposure region which is exposed using the first photomask and an exposure region which is exposed using the second mask.

Here, the first photo mask may form an exposure pattern for the first exposure region 701a and the third exposure region 701c, for example, and the exposure pattern for the third exposure region 701c may be formed with optical transmissivity lower than optical transmissivity of the exposure pattern for the first exposure region 701a. In the same manner, the second photo mask may form an exposure pattern for the second exposure region 701b and the third exposure region 701c, for example, and the exposure pattern for the third exposure region 701c may be formed with optical transmissivity lower than optical transmissivity of the exposure pattern for the second exposure region 701b.

FIG. 9 is a schematic graph for explaining a modification of the manufacturing method of a TFT substrate of the embodiment 3.

In the graph shown in FIG. 9, a relative value of exposure quantity QOE of the photosensitive resist is taken on an axis on abscissas, and the gap LCT between the pixel electrode 108 and the counter electrode 109 is taken on an axis of ordinates.

In forming the etching resist on the conductive film in the manufacturing method of the TFT substrate 1, the etching resist is usually formed using a negative photosensitive resist. That is, for example, the etching resist used for forming the pixel electrodes 108 and the counter electrodes 109 is formed by exposing portions where the pixel electrodes 108 and the counter electrodes 109 are formed in the negative photosensitive resist which is formed on the whole surface of the conductive film (for example, ITO film).

Here, the relationship between the exposure quantity QOE of the photosensitive resist and the gap LCT between the formed pixel electrode 108 and counter electrode 109 may exhibit a relationship shown in FIG. 9, for example. That is, assuming a minimum exposure quantity for completely exposing the photosensitive resist as 1, the gap LCT between the pixel electrode 108 and the counter electrode 109 assumes a gap LCT_{L} which constitutes a designed value. Here, when the photosensitive quantity QOE is larger than 1, the gap LCT becomes smaller than the designed value LCT_{L}, while when the photosensitive quantity QOE is smaller than 1, the gap LCT becomes larger than the designed value LCT_{L}.

Accordingly, for example, when the third exposure region 701c is exposed by the method shown in FIG. 8A and FIG. 8B, in forming the pixel electrodes 108 and the counter electrodes 109, by changing a total quantity of the exposure quantity of exposure to the third exposure region 701c by the second light source and the exposure quantity of the exposure to the third exposure region 701c by the first light source, it is possible to adjust the gap LCT between the pixel electrode 108 and the counter electrode 109 formed in the third exposure region 701c to an arbitrary size.

### Embodiment 4

In the embodiment 1 to the embodiment 3, the explanation has been made with respect to the exposure method in which, in the step of exposing the photosensitive resist, one region 701 is divided into the plurality of exposure regions, and the respective exposure regions are individually exposed and hence, image quality irregularities which occur on the boundary portion between two neighboring exposure regions at the time of exposing the whole one region 701 can be easily reduced.

That is, the embodiment 1 to the embodiment 3 provide the exposure method which can easily reduce image quality irregularities which occur due to an error of the light source or the control mechanism of the light source which occurs on the boundary portion of the exposure regions which are exposed by the different light sources or an error of alignment of photo masks which occurs on the boundary portion between the exposure regions which are exposed by different photo masks, for example.

However, in performing the exposure using the direct-drawing exposure-method exposure device having two independent light sources 8a, 8b shown in FIG. 3C, for example, there may be a case that in the first exposure region 701a which is exposed by one light source 8a, for example, the exposure quantity irregularities occur or the exposure position is displaced. As a result, for example, in-plane irregularities occur with respect to channel lengths or channel widths of TFT elements of respective pixels formed in the first exposure region 701a or the gap between the pixel electrode 108 and the counter electrode 109 thus causing image quality irregularities.

To prevent the image quality irregularities attributed to the size irregularities or the positional displacement of the TFT elements or the like in one exposure region which is exposed by the same light source in this manner, for example, with respect to one or a plurality of TFT substrates formed through a series of processes, the sizes of the scanning signal lines 101, the sizes of the video signal lines 102, the sizes of the TFT elements, the sizes of the pixel electrodes 108 and the like are measured and, thereafter, the sizes acquired by such measurement and numerical value data used in the exposure which is performed for forming an object to be measured (measuring object) may be compared to each other, and the numerical value data may be corrected in accordance with a result of such a comparison.

That is, for example, sizes and positions of the video signal lines 102 formed on the insulation substrate 100, and sizes and positions of the drain electrodes and source electrodes 106 of the TFT elements formed on the insulation substrate 100 are measured and, thereafter, the sizes and positions acquired by such measurement and numerical value data which is used in the exposure which is performed for forming the video signal lines 102, the drain electrodes and the source electrodes 106 of the TFT elements are compared to each other. When the differences between the sizes and positions acquired by the measurement and the numerical value data are larger than preset values (threshold values), based on a result of the comparison, the corresponding numerical value data is corrected such that the sizes and positions of the formed video signal lines 102, and drain electrodes and source electrodes 106 of the TFT elements approximate designed values. Due to such correction, image quality irregularities in one exposure region (for example, the first exposure region 701a) can be also reduced.

Further, in adding the above-mentioned measuring step and correcting step to the manufacturing method of the TFT substrate explained in conjunction with the embodiment 1 to the embodiment 3, by performing the measurement and the correction for every exposure region, for example, it is possible to easily reduce image quality irregularities which occur on the boundary portion between two neighboring exposure regions and image quality irregularities in each exposure region. That is, the image irregularities can be further reduced compared to the manufacturing method explained in conjunction with the embodiment 1 to the embodiment 3.

Although the present invention has been specifically explained heretofore in conjunction with the above-mentioned embodiments, it is needless to say that the present invention is not limited to the above-mentioned embodiments, and various modifications are conceivable in a range not departing from the gist of the present invention.

For example, in the embodiment 1 to the embodiment 4, the manufacturing method of a TFT substrate 1 used in the liquid crystal display panel is exemplified. However, the present invention is not limited to such a manufacturing method and is also applicable to a manufacturing method of a substrate having the substantially same constitution as the TFT substrate (for example, a substrate used in a self-luminous type display device using organic EL elements).

Further, in the embodiment 1 to the embodiment 4, the explanation has been made by exemplifying the manufacturing method of a TFT substrate 1 in which one pixel has the constitution shown in FIG. 2A to FIG. 2C, for example. However, the present invention is not limited to such a manufacturing method and is also applicable to a manufacturing method of a TFT substrate 1 in which one pixel has the constitution different from such constitution.

What is claimed is:

1. A manufacturing method of a display device which performs, in a series of processes of forming a plurality of scanning signal lines, a plurality of video signal lines, a plurality of TFT elements and a plurality of pixel electrodes on a preliminarily determined one region on a surface of an insulation substrate, an exposure/development step including a step of exposing a formed film made of a photosensitive material and a step of developing an exposed film made of the photosensitive material a plurality of times, wherein
said each exposure step is performed using an exposure device such that the whole of said one region is exposed by dividing said one region into a plurality of exposure regions and by individually exposing the respective exposure regions, and
said each exposure step is performed such that said one region is divided into the plurality of exposure regions by a boundary line which has no overlapping portion and is not aligned with a boundary line between the exposure regions in the exposure step for at least one time out of other exposure steps, and the plurality of exposure regions is exposed.

2. A manufacturing method of a display device according to claim 1, wherein the boundary line between the exposure regions in the exposure step which is performed for forming the video signal lines is not aligned with the boundary line between the exposure regions in the exposure step which is performed for forming the pixel electrodes.

3. A manufacturing method of a display device according to claim 1, wherein said one region is divided into a plurality of exposure regions using a boundary line which is constituted of a line segment which extends in an extension direction of the video signal lines formed in said one region and a line segment which extends in an extension direction of the scanning signal lines formed in said one region.

4. A manufacturing method of a display device according to claim 3, wherein the exposure step which is performed for forming the video signal lines is performed such that said one region is divided into the plurality of exposure regions by the boundary line which does not pass a region of said one region where the TFT element is formed, and the plurality of exposure regions is exposed.

5. A manufacturing method of a display device according to claim 3, wherein the exposure step which is performed for forming the pixel electrodes is performed such that said one region is divided into the plurality of exposure regions by the boundary line which does not pass a region of said one region where the pixel electrode is formed, and the plurality of exposure regions is exposed.

6. A manufacturing method of a display device according to claim 3, wherein the exposure step which is performed for forming the pixel electrodes is performed such that said one region is divided into the plurality of exposure regions by the boundary line which is constituted of a line segment which passes a region of said one region where the video signal line is formed and a line segment which passes a region of said one region where the scanning signal line passes, and the plurality of exposure regions is exposed.

7. A manufacturing method of a display device which performs, in a process of forming a plurality of scanning signal lines, a plurality of video signal lines, a plurality of TFT elements and a plurality of pixel electrodes on a preliminarily determined one region on a surface of an insulation substrate, an exposure/development step including a step of exposing a formed film made of a photosensitive material and a step of developing an exposed film made of the photosensitive material a plurality of times, wherein
said each exposure step is performed using an exposure device such that the whole of said one region is exposed by dividing said one region into a plurality of exposure regions and by individually exposing the respective exposure regions, and
said each exposure step is performed such that said one region is divided into the plurality of exposure regions in a state that a boundary portion of two neighboring exposure regions has a partial region where two neighboring regions overlap with each other, and said one partial region is divided into a plurality of first small regions which forms a portion of one exposure region out of said two neighboring exposure regions and a plurality of second small regions which forms a portion of another exposure region out of said two neighboring exposure regions in a mosaic arrangement, and the small regions are exposed.

8. A manufacturing method of a display device according to claim 7, wherein the partial regions in the respective exposure steps overlap with each other, and
the arrangement of the first small regions and the second small regions in said one partial region in each exposure step is set different from the arrangement of the first small regions and the second small regions of the partial region which overlaps with the partial region in the exposure step for at least one time out of said other exposure steps.

9. A manufacturing method of a display device according to claim 8, wherein the arrangement of the first small regions and the second small regions in the partial region in the exposure step which is performed for forming the video signal lines is set different from the arrangement of the first small regions and the second small regions in the partial region in the exposure step which is performed for forming the pixel electrodes.

10. A manufacturing method of a display device which performs, in a series of processes of forming a plurality of scanning signal lines, a plurality of video signal lines, a plurality of TFT elements and a plurality of pixel electrodes on a preliminarily determined one region on a surface of an insulation substrate, an exposure/development step including a step of exposing a formed film made of a photosensitive material and a step of developing an exposed film made of the photosensitive material a plurality of times, wherein
said each exposure step is performed using an exposure device such that the whole of said one region is exposed by dividing said one region into a plurality of exposure regions and by individually exposing the exposure regions, and
said each exposure step is performed such that said one region is divided into the plurality of exposure regions in a state that a boundary portion of two neighboring exposure regions has a partial region where two neighboring regions overlap with each other, and
the partial region is exposed together with one exposure region out of said two neighboring exposure regions and, thereafter, is exposed together with another exposure region out of said neighboring exposure regions.

11. A manufacturing method of a display device according to claim 10, wherein said one partial region is exposed such that a sum of exposure quantity for the partial region is substantially equal to exposure quantity for said one exposure region and exposure quantity for said another exposure region.

12. A manufacturing method of a display device according to claim 11, wherein said each exposure step is performed such that said one region is divided into the plurality of exposure regions while preventing a portion or the whole of the partial region from overlapping with the partial region in the exposure step for at least one time out of said other exposure steps.

13. A manufacturing method of a display device according to claim 12, wherein the partial region in the exposure step which is performed for forming the video signal lines has a partial region or the whole region thereof not overlapped with the partial region in the exposure step which is performed for forming the pixel electrodes.

14. A manufacturing method of a display device according to claim 1, wherein the counter electrodes are formed together with the pixel electrodes at the time of forming the pixel electrodes.

15. A manufacturing method of a display device according to claim 1, wherein the exposure device includes a plurality of photo masks which is prepared for the respective exposure regions and, in the exposure step for one time, the plurality of exposure regions is sequentially exposed by repeating an exchange of the photo masks and moving of an exposure position.

16. A manufacturing method of a display device according to claim 1, wherein the exposure device includes a plurality of independent light sources, a moving means which moves relative positions between the respective light sources and the insulation substrate, and a control means which controls radiation/non-radiation of lights from the light source based on preliminarily prepared numerical data, and
in the exposure step for one time, the different exposure regions are exposed in parallel using the plurality of respective light sources.

17. A manufacturing method of a display device according to claim 16, wherein in addition to said series of processes for forming the plurality of scanning signal lines, the plurality of video signal lines, the plurality of TFT elements and the plurality of pixel electrodes on said one region out of the surface of the insulation substrate, the manufacturing method further comprises the steps of:
measuring at least one of a size of the plurality of scanning signal lines formed through the process, a size of the plurality of video signal lines formed through the process, a size of a plurality of TFT elements formed through the process, and a size of the plurality of pixel electrodes formed through the process; and
comparing the sizes measured in the measuring step and the numerical data used in the exposure step which is performed for forming an object whose size is to be measured, and correcting the numerical data when necessary, and
the measuring step and the correcting step are performed individually for every exposure region.
